(19) United States
(12) Patent Application Publication
(10) Pub. No.: US 2025/0170827 A1
(43) Pub. Date: May 29, 2025

(54) DEVICE MANUFACTURING METHOD, HEAD MANUFACTURING METHOD, PIEZOELECTRIC DEVICE, LIQUID DISCHARGE HEAD, LIQUID DISCHARGE APPARATUS

(71) Applicant: Makoto TANAKA, Tokyo (JP)

(72) Inventor: Makoto TANAKA, Tokyo (JP)

(21) Appl. No.: 18/878,093

(22) PCT Filed: Jul. 5, 2023
(86) PCT No.: PCT/IB2023/056938

§ 371 Date: Dec. 23, 2024

(30) Foreign Application Priority Data
Jul. 26, 2022 (JP) 2022-118758

(51) Int. Cl. B41J 2/14; B41J 2/16; H10N 39/00

(52) U.S. Cl. CPC B41J 2/14233; B41J 2/1433; B41J 2/1606; B41J 2/162; H10N 39/00

(57) ABSTRACT

A device manufacturing method for manufacturing a piezoelectric device, the device manufacturing method includes: forming a CMOS element on a first surface of a substrate; forming a piezoelectric element over the first surface of the substrate on which the CMOS element is formed; forming a first insulating film in a region where the piezoelectric element is formed when forming the CMOS element or the piezoelectric element, forming a lower electrode layer, a piezoelectric layer, an upper electrode layer, and a second insulating film on the first insulating film when forming the piezoelectric element; and forming a CMOS wiring layer of the CMOS element and a piezoelectric wiring layer of the piezoelectric element after forming the CMOS element and the piezoelectric element on the substrate.

### TECHNICAL FIELD

The present embodiment relates to a device manufacturing method, a head manufacturing method, a piezoelectric device, a liquid discharge head, and a liquid discharge apparatus.

### BACKGROUND ART

Attempts have been made to use piezoelectric devices that vibrate thin films in various fields. The piezoelectric device is used, for example, in medicine, industry, and the like, and is used among them, for example, in a liquid discharge head.

As a liquid discharge apparatus using the liquid discharge head, a liquid discharge apparatus using a thermal system (or a bubble system) and a piezoelectric system is known.

The thermal system has a small size, high density, and ultra-low cost as main characteristics (advantages), and is widely used in inkjet printers for offices, small office home office (SOHO), and homes. A major reason for the small size, high density, and ultra-low cost is a simple structure and complementary metal oxide semiconductor (MOS) (CMOS) on-chip (a CMOS can be formed on the same substrate as a droplet discharge thermal element). In contrast, the thermal system has a disadvantage that a degree of freedom in ink and driving durability are lower than those of the piezoelectric system, and is slightly behind in commercial and industrial printers.

The piezoelectric system has main characteristics (advantages) of high driving force (high viscosity and large droplet discharge), high degree of freedom in ink, and high driving durability, and is widely used in inkjet printers for commercial and industrial use. Although this is also used in inkjet printers for offices, SOHO, and homes, this is significantly inferior in cost competitiveness to the thermal system.

In a piezoelectric system liquid discharge apparatus, a piezoelectric material of lead zirconate titanate (PZT) is usually used, and is usually formed at high temperature of about 850° C. In an optical device or an ultrasonic device, a CMOS integrated piezoelectric element using PZT or another piezoelectric material formed at temperature lower than this temperature has been proposed.

For example, Patent Literature 1 discloses a droplet discharger including a substrate including a nozzle surface, an electronic component integrated with the substrate, a nozzle-forming layer on the nozzle surface of the substrate, and a piezoelectric actuator on the nozzle-forming layer, and discloses that the electronic component includes a CMOS electronic component integrated with the substrate. An object of Patent Literature 1 is to reduce acoustic crosstalk between piezoelectric droplet dischargers and achieve a larger number of nozzles.

Patent Literature 1 discloses that the piezoelectric body is formed of one or a plurality of piezoelectric materials that can be processed at temperature lower than 450° C. Patent Literature 1 points out that integrated electronic components (for example, CMOS electronic components) deteriorate when the temperature exceeds 300° C. or 450° C., and discloses that using a piezoelectric material that can be processed at temperature lower than 450° C. enables processing of a piezoelectric actuator and integration of electronic components.

### Technical Problem

Although a piezoelectric system liquid discharge head is required to have excellent piezoelectric characteristics with a large driving force, a CMOS integrated piezoelectric element that enables this is not put into practical use, and there is no example of putting this on the market. From the viewpoint of management of a manufacturing step, the viewpoint of securing various characteristics of the obtained liquid discharge apparatus, and the like, it has been difficult to implement a liquid discharge head using the CMOS integrated piezoelectric element. For example, when the formation temperature of the piezoelectric element is lowered as in Patent Literature 1, there has been a disadvantage that a piezoelectric performance (driving force) of the piezoelectric element is significantly deteriorated or this does not function as the piezoelectric element. In contrast, when the formation temperature of the piezoelectric element is increased, a disadvantage arises that the CMOS element is deteriorated.

Also when a technology of driving and vibrating the piezoelectric element in the liquid discharge head is to be applied to other applications, it is desired to implement the CMOS integrated piezoelectric element. In this case, it is required that a CMOS operation may be performed and excellent piezoelectric characteristics are obtained.

Therefore, an object of the present embodiment is to provide a piezoelectric device including a CMOS element and a piezoelectric element on the same substrate, and achieving both the CMOS operation and excellent piezoelectric characteristics.

### Solution to Problem

In a device manufacturing method for manufacturing a piezoelectric device, the device manufacturing method includes: forming a CMOS element on a first surface of a substrate; forming a piezoelectric element over the first surface of the substrate on which the CMOS element is formed; forming a first insulating film in a region where the piezoelectric element is formed when forming the CMOS element or the piezoelectric element, forming a lower electrode layer, a piezoelectric layer, an upper electrode layer, and a second insulating film on the first insulating film when forming the piezoelectric element; forming a CMOS wiring layer of the CMOS element and a piezoelectric wiring layer of the piezoelectric element after forming the CMOS element and the piezoelectric element on the substrate; and forming a void in the substrate from a second surface opposite to the first surface of the substrate after forming the CMOS wiring layer and the piezoelectric wiring layer on the substrate.

A piezoelectric device includes: a substrate having a void; a CMOS element on a first surface of the substrate; and a piezoelectric element on the first surface of the substrate, the piezoelectric element including: a lower electrode layer having a first surface on the first surface of the substrate; a piezoelectric layer having a first surface on a second surface opposite to the first surface of the lower electrode layer; an upper electrode layer having a first surface on a second surface opposite to the first surface of the piezoelectric layer; a first insulating film on the first surface of the lower electrode layer; and a second insulating film on the second surface of the upper electrode layer, the second insulating film having a thickness thicker than the first insulating film.

### Advantageous Effects of Invention

According to the present embodiment, it is possible to provide a piezoelectric device including a CMOS element and a piezoelectric element on the same substrate and achieving both a CMOS operation and excellent piezoelectric characteristics.

### BRIEF DESCRIPTION OF DRAWINGS

A more complete appreciation of embodiments of the present disclosure and many of the attendant advantages and features thereof can be readily obtained and understood from the following detailed description with reference to the accompanying drawings.

FIG. 1 is a schematic view illustrating an example of a piezoelectric device according to the present embodiment;

FIG. 2 is a schematic view illustrating an example of a piezoelectric element;

FIGS. 3A and 3B are schematic views for explaining an example of vibration;

FIGS. 4A and 4B are schematic views for explaining an example of vibration;

FIGS. 5A and 5B are schematic views for explaining an example of vibration; in which FIG. 5A is an example of a case not included in the present embodiment, and FIG. 5B is an example of a case included in the present embodiment;

FIG. 6A is a schematic view for explaining a nozzle plate vibration system, and FIG. 6B is a schematic view for explaining a conventional discharge system;

FIG. 7 is a schematic view illustrating an example of a liquid discharge head according to the present embodiment;

FIG. 8 is a schematic view illustrating another example of the liquid discharge head according to the present embodiment;

FIG. 9 is a flowchart explaining an example of a method of manufacturing a piezoelectric device;

FIG. 10 is a flowchart explaining an example of a difference in various characteristics;

FIGS. 11A and 11B are schematic views explaining an example of a CMOS element forming step;

FIGS. 11C to 11E are schematic views explaining an example of a CMOS element forming step;

FIGS. 11F to 11H are schematic views explaining an example of a CMOS element forming step;

FIGS. 12A and 12B are schematic views explaining an example of a piezoelectric element forming step;

FIGS. 12C and 12D are schematic views explaining an example of a piezoelectric element forming step;

FIG. 12E is a schematic view explaining an example of a piezoelectric element forming step, and FIG. 12F is a schematic view explaining an example of a void forming step;

FIG. 13 is a schematic view of an example of a liquid discharge apparatus;

FIG. 14 is a schematic view of another example of a liquid discharge apparatus;

FIG. 15 is a schematic view of an example of a liquid discharge device according to an embodiment of the present disclosure; and

FIG. 16 is a schematic view of a liquid discharge device according to another embodiment of the present disclosure.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DESCRIPTION OF EMBODIMENTS

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

Hereinafter, a piezoelectric device, a liquid discharge head, a liquid discharge apparatus, a method of manufacturing the piezoelectric device, and a method of manufacturing the liquid discharge head according to the present embodiment will be described with reference to the drawings. The present embodiment is not limited to the embodiments described below, and changes such as other embodiments, additions, modifications, and deletions can be made within the scope that can be conceived by those skilled in the art, and any aspect is included in the scope of the present embodiment as long as the function and effect of the present embodiment are achieved.

### [Piezoelectric Device]

When a CMOS element and a piezoelectric element are formed on the same substrate (for example, a Si substrate), it is required to first form the CMOS element and then form the piezoelectric element from the viewpoint of step management to avoid contamination of a semiconductor manufacturing line with heavy metals, alkalis, and the like. In this case, in order to secure (maintain) various characteristics of the previously formed CMOS, it is required to form the piezoelectric element at temperature lower than formation temperature of the CMOS.

In contrast, when the formation temperature of the piezoelectric element is lowered, piezoelectric performance (driving force) of the piezoelectric element is significantly deteriorated, or the piezoelectric element does not function as the piezoelectric element. Therefore, it has been difficult to implement a piezoelectric device using a CMOS integrated piezoelectric element. That is, it has been difficult so far to implement the piezoelectric device in which the CMOS integrated piezoelectric element in which an operation of the CMOS element is secured and excellent piezoelectric characteristics of the piezoelectric element are secured is arranged.

When the piezoelectric device is used as a liquid discharge head or the liquid discharge apparatus, it has been difficult so fat to implement the liquid discharge head or a liquid discharge apparatus including the CMOS integrated piezoelectric element in which the operation of the CMOS element is secured and a droplet discharge operation is secured. The CMOS integrated piezoelectric element refers to a configuration in which the CMOS element and the piezoelectric element are arranged on the same substrate.

If the CMOS element can be manufactured on the same substrate as the piezoelectric element, an area of electrode wiring and electrode mounting can be reduced, and a chip area of the piezoelectric element can be significantly reduced. In this case, for example, the chip area of the piezoelectric element is about 1/10. Since the number of components can also be reduced, it becomes possible to provide a small, high-density, and low-cost liquid discharge apparatus by a piezoelectric system.

However, in order to obtain the piezoelectric element with high driving force (high performance) that can discharge droplets, formation temperature of about 850° C. is usually required, and this breaks the previously formed CMOS element. The breakdown of the CMOS element specifically is, for example, an operation failure due to a threshold voltage shift of a P-channel metal oxide semiconductor (PMOS) and an N-channel metal oxide semiconductor (NMOS), elution or disconnection of metal wiring, a crack or dielectric breakdown of an insulating layer, and the like. In contrast, when the formation temperature of the piezoelectric element is made lower than usual, the piezoelectric element does not exhibit desired piezoelectric performance (piezoelectric characteristics).

In order to form the CMOS element and the piezoelectric element on the same substrate, an appropriate devise is required, and the inventor of the present embodiment conducted intensive studies. When the piezoelectric element is formed after the CMOS element is formed, it is considered that the piezoelectric element is required to be formed at the formation temperature of, for example, 500° C. or lower in order to avoid a damage to the wiring (for example, metal wiring and an interlayer insulating film) to the CMOS element. However, when the piezoelectric element is formed at such formation temperature, the piezoelectric characteristics are deteriorated.

Therefore, after forming the CMOS element, the piezoelectric element was formed at formation temperature in a predetermined range before forming the CMOS wiring. When appropriately studying manufacturing conditions, a configuration in which a desired CMOS operation can be performed and excellent piezoelectric characteristics can be obtained also when the CMOS element and the piezoelectric element are formed on the same substrate was found.

In order to form the CMOS element and the piezoelectric element on the same substrate and enable a more excellent CMOS operation and excellent piezoelectric characteristics, it is also required to devise a manufacturing method. Although the manufacturing method will be described later in detail, in the manufacturing method of the present embodiment, for example, measures are taken such as changing the order of steps in a conventional manufacturing method. In the manufacturing method of the present embodiment, after the CMOS element is formed, the piezoelectric element is formed, and then wiring to the CMOS element is formed. This makes it possible to avoid damage to the CMOS element and the wiring to the CMOS element. In such manufacturing method, for example, a predetermined relationship occurs in thicknesses of insulating films.

A piezoelectric device according to the present embodiment includes a CMOS element and a piezoelectric element formed on the same substrate, the piezoelectric element including a lower electrode layer, a piezoelectric layer, and an upper electrode layer, the substrate including a void on a side opposite to the piezoelectric layer across the lower electrode layer, the piezoelectric device includes a first insulating film on a lower side of the lower electrode layer and a second insulating film on an upper side of the upper electrode layer, the first insulating film under the piezoelectric layer thinner than the second insulating film above the piezoelectric layer.

According to the present embodiment, it is possible to provide the piezoelectric device including the CMOS element and the piezoelectric element on the same substrate and achieving both the CMOS operation and excellent piezoelectric characteristics. The piezoelectric device of the present embodiment can secure various characteristics of the CMOS element, and can obtain excellent piezoelectric characteristics having excellent driving force while maintaining the CMOS element operation.

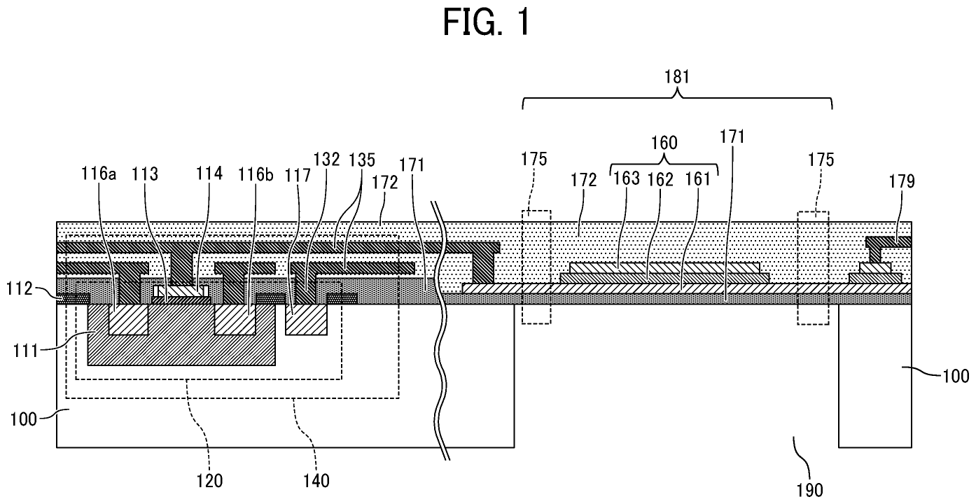

FIG. 1 is a schematic view for explaining an example of the piezoelectric device of the present embodiment.

In the piezoelectric device in this example, a CMOS element 120 and a piezoelectric element 160 are formed on the same silicon substrate 100. The silicon substrate 100 may be a P-type substrate or an N-type substrate. In this example, the P-type substrate is used.

The CMOS element 120 in this example includes an N well 111, a gate oxide film 113, a gate electrode 114, a source electrode 116a, a drain electrode 116b, and a substrate electrode 117. In this example, the CMOS element 120 and a wiring layer are distinguished from each other, and a portion including the CMOS element 120 and a part of the wiring layer is made a CMOS component 140.

The N well 111 is a CMOS well. The CMOS well may be an N well or a P well. In this example, N well is used.

A field oxide film 112 is an element isolation insulating film. It is possible that the CMOS element 120 includes the field oxide film 112 or not.

The CMOS is formed of a combination of the NMOS and PMOS. In the drawings in this example, only the PMOS is illustrated and that related to the NMOS is omitted for convenience.

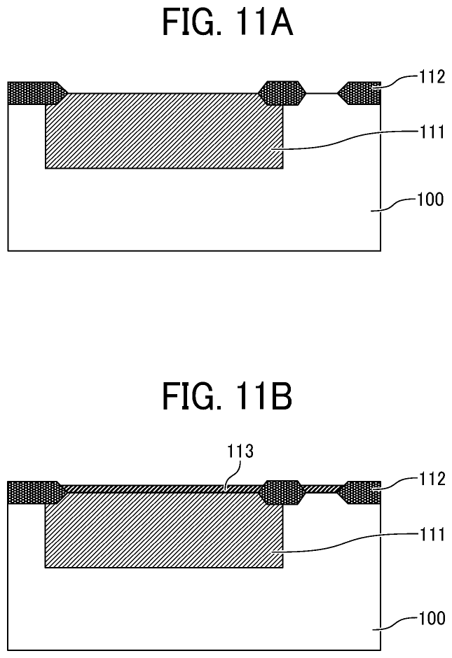

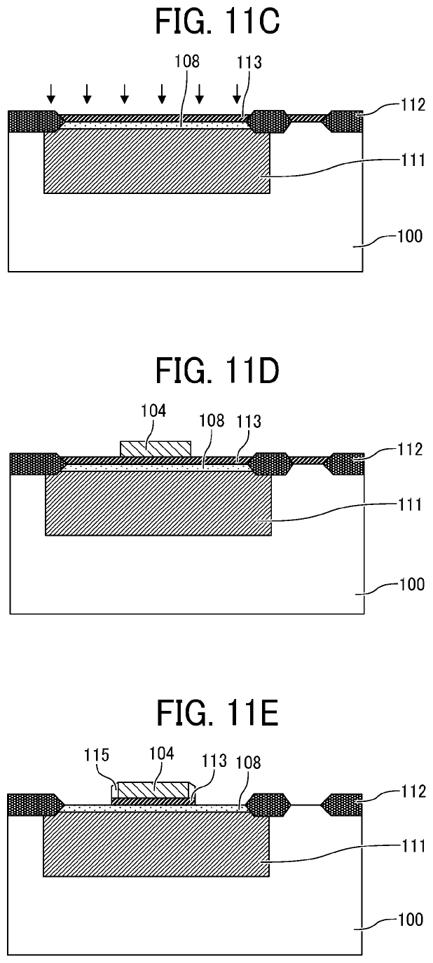

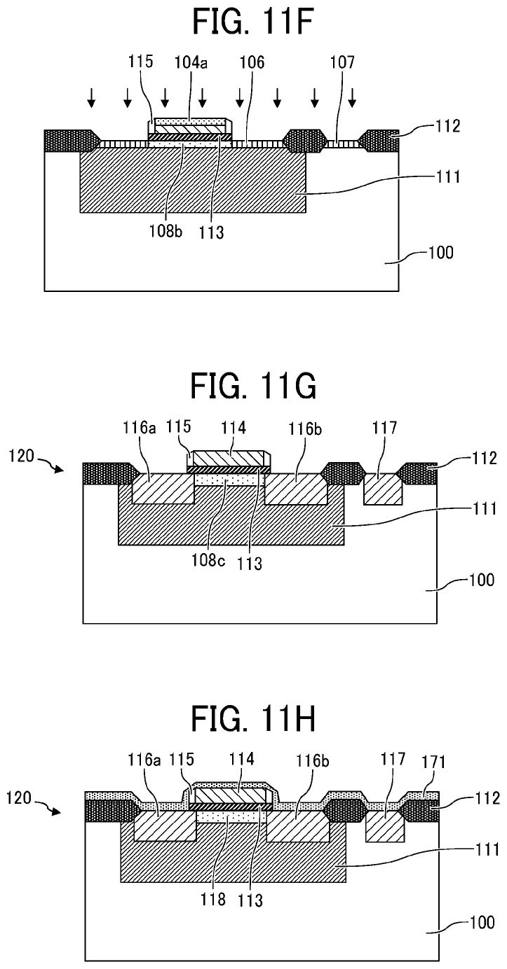

A sidewall 115 is formed on the gate electrode 114, and the sidewall 115 is omitted in FIG. 1. The sidewall 115 is illustrated in FIGS. 11E and 11F to 11H. The gate electrode 114 is not subjected to impurity diffusion.

The source electrode 116a, the drain electrode 116b, and the substrate electrode 117 are formed by, for example, high-concentration impurity ion implantation, and may be referred to as an impurity diffusion layer and the like. In the drawing, the source electrode 116a and the drain electrode 116b may be reversed.

As the wiring layer, a contact hole 132, metal wiring 135, and an interlayer insulating film are illustrated in the drawing. The interlayer insulating film is formed between the metal wiring 135 and the metal wiring 135. A reference sign of the interlayer insulating film is herein omitted.

The wiring layer can have, for example, a multilayer structure. For example, it is possible to sequentially form a contact hole, a first layer of metal wiring (metal 1), an insulating interlayer film (interlayer film 1), a through hole, a second layer of metal wiring (metal 2), . . . , an insulating interlayer film (interlayer film n), a through hole, an n-th layer of metal wiring (metal n), and the like to form the wiring layer. In this example, the metal wiring 135 includes two layers.

The contact hole 132 is provided to obtain electrical contact with the gate electrode 114, the source electrode 116a, the drain electrode 116b, and the substrate electrode 117. The through hole is provided to obtain electrical contact between the metal wiring and the metal wiring.

As metal used for the wiring, for example, an aluminum-based material can be used. A copper-based material having low resistance and withstanding higher temperature can also be used. In the present embodiment, there is no limitation, and other materials can be used as appropriate.

As the insulating interlayer film, a silicon oxide film by a chemical vapor deposition (CVD) method is generally used. A silicon nitride film having high moisture resistance is also often used as an alternative layer or an additional layer. In the present embodiment, there is no limitation, and other films can be used as appropriate.

The piezoelectric element 160 in this example includes a lower electrode layer 161, a piezoelectric layer 162, and an upper electrode layer 163. The piezoelectric element 160 is coupled to the CMOS element 120 via the metal wiring 135. In the drawing, the metal wiring 135 and the lower electrode layer 161 are coupled to each other, but there is no limitation, and the metal wiring 135 and the upper electrode layer 163 may be coupled to each other.

In the drawing, a displacement portion 175 is indicated by a broken line. The displacement portion 175 is a region where the piezoelectric element 160 is not formed, and is a portion that is significantly deformed and displaced when a voltage is applied to the piezoelectric element 160. When the displacement portion 175 is deformed, a vibration region 181 vibrates.

As the lower electrode layer 161 and the upper electrode layer 163, for example, platinum (Pt) can be used, but there is no limitation, and a conductive metal material and the like can be used. The lower electrode layer 161 and the upper electrode layer 163 may be made of the same material or different materials.

The lower electrode layer may be referred to as a first electrode and the like, and the upper electrode layer may be referred to as a second electrode and the like. The lower electrode layer may be a common electrode and the upper electrode layer may be an individual electrode, or the lower electrode layer may be an individual electrode and the upper electrode may be an individual electrode.

For example, lead zirconate titanate (PZT) or potassium sodium niobate (KNN) can be used for the piezoelectric layer 162. It is preferable to use PZT for the piezoelectric layer 162.

A method of forming the piezoelectric layer 162 is not particularly limited, and can be appropriately selected. In the case of PZT, a sol-gel method or a sputtering method is common, but a chemical vapor deposition (CVD) method may be used, and the method is not limited thereto.

The silicon substrate 100 includes a void 190 on the side opposite to the piezoelectric layer 162 with the lower electrode layer 161 interposed therebetween. Since the void 190 is provided, the vibration region 181 can vibrate. When the piezoelectric device is the liquid discharge head or the liquid discharge apparatus, the void 190 is a liquid chamber. The void 190 is, for example, a cylindrical opening opened in the silicon substrate 100.

When a drive voltage is applied between the lower electrode layer 161 and the upper electrode layer 163, mechanical deformation occurs in the piezoelectric layer 162. When vibration at a predetermined frequency is generated due to periodic variation of the drive voltage, the vibration region 181 vibrates to generate an ultrasonic wave or to discharge droplets in a case of the liquid discharge head.

The piezoelectric device of the present embodiment may include a through hole that penetrates the piezoelectric element 160 and communicates with the void 190; in this case, the piezoelectric element 160 is formed around the through hole. The through hole thus formed can be a nozzle hole that discharges liquid when the piezoelectric device is the liquid discharge head.

The piezoelectric device of this example includes a first insulating film 171 on a lower side of the lower electrode layer 161 and a second insulating film 172 on an upper side of the upper electrode layer 163. The first insulating film 171 under the piezoelectric layer 162 is thinner than the second insulating film 172 above the piezoelectric layer 162. Although the method of manufacturing the piezoelectric device will be described later in detail, in the present embodiment, the CMOS element 120 and the piezoelectric element 160 are formed on the silicon substrate 100, and then the wiring layer is formed. By manufacturing in such order, the first insulating film 171 under the piezoelectric layer 162 becomes thinner than the second insulating film 172 above the piezoelectric layer 162. It is defined “under the piezoelectric layer” and “above the piezoelectric layer” in order to clarify a place where the thicknesses of the insulating films are compared with each other.

The method of manufacturing the piezoelectric device of the present embodiment is different from the conventional manufacturing method of forming the wiring layer for the CMOS element and then forming the piezoelectric element. In the method of manufacturing the piezoelectric device of the present embodiment, after the CMOS element is formed, the piezoelectric element is formed, and then the wiring layer is formed. In a case of the manufacturing method as in the present embodiment, the second insulating film 172 (upper insulating film) is thicker than the first insulating film 171 (lower insulating film) for the reason described below. For example, the second insulating film 172 is manufactured to be several times thicker than the first insulating film 171.

When the CMOS element and the piezoelectric element are manufactured on the same substrate, and the wiring layer for the CMOS element is further formed after the piezoelectric element is formed, a layer for forming the interlayer insulating film is formed also on the piezoelectric element at the same time when the interlayer insulating film in the wiring layer for the CMOS element is formed. Together with a protective insulating film of the piezoelectric element, the insulating film on the piezoelectric element becomes thicker. For this reason, in the present embodiment, the second insulating film (upper insulating film) is thicker than the first insulating film (lower insulating film); in other words, the first insulating film is thinner than the second insulating film. Although described a little with reference to FIGS. 3A to 5B mentioned later, when a diaphragm is vibrated by the piezoelectric system, it is required to make one of the upper insulating film and the lower insulating film thick (thin). When they have the same thickness, it is not possible to vibrate. Therefore, the first insulating film and the second insulating film have different thicknesses.

At that time, it is considered that vibration is also possible by making the first insulating film thicker than the second insulating film. However, if it is attempted to make the first insulating film thicker than the second insulating film, the layer for forming the interlayer insulating film is formed also on the piezoelectric element at the same time when the interlayer insulating film in the wiring layer for the CMOS element is formed, so that a total thickness of the insulating film in the vibration region increases. Therefore, when it is attempted to make the first insulating film thicker than the second insulating film, the total thickness of the insulating film in the vibration region increases, an excellent displacement amount cannot be secured, and excellent piezoelectric characteristics cannot be obtained. In particular, in a case of a nozzle plate vibration system liquid discharge head, it is difficult to perform an excellent droplet discharge operation.

The nozzle plate 251 (nozzle vibration plate) includes the first insulating film 171 (lower insulating film), piezoelectric element 160, the second insulating film 172 (upper insulating film), and layers such as a resin layer over the second insulating film 172. In order to obtain desired vibration characteristics, the film thickness, rigidity, film stress, dimensions (for example, the width of the diaphragm and the like) and the like of each layer are preferably formed precisely in advance to be designed and manufactured. Especially, the thickness of each layers are controlled precisely to obtain the desired vibration characteristics.

The first insulating film 171 and the second insulating film 172 can be appropriately selected, and for example, a silicon oxide film, a silicon nitride film, a laminated film of the silicon oxide film and the silicon nitride film, and the like can be used. As the first insulating film 171 and the second insulating film 172, for example, a silicon oxide film by a CVD method is generally used. A silicon nitride film having high moisture resistance is also often used as an alternative layer or an additional layer. In the present embodiment, there is no limitation, and other films can be used as appropriate.

A portion including the first insulating film 171, the second insulating film 172, and the piezoelectric element 160 in the vibration region 181 may be referred to as a diaphragm and the like. The diaphragm is a portion that affects piezoelectric characteristics, and the piezoelectric characteristics are affected by not only characteristics (piezoelectric characteristics, rigidity, various dimensions, and the like) of the piezoelectric element 160 but also the film thicknesses and materials of the first insulating film 171 and the second insulating film 172.

The piezoelectric device of the present embodiment can be used not only for the liquid discharge head but also for various purposes. Although the present embodiment has been obtained in the process of developing the liquid discharge apparatus, an application range of the technology of the present embodiment is not limited to the liquid discharge apparatus. The piezoelectric device of the present embodiment can be made the piezoelectric device having a higher driving force than that of the conventional piezoelectric device, and the application range thereof is not limited to the liquid discharge apparatus. The piezoelectric device according to the present embodiment can be applied to a wide variety of small devices, functional devices, and the like, such as a micro infusion pump that precisely transports a small amount of liquid, an optical system (deflection) device such as a projector, an ultrasonic (generation, detection, vibration) system device, a hearing aid, for example. In addition, for example, application to a medical ultrasonic diagnostic apparatus and the like is possible.

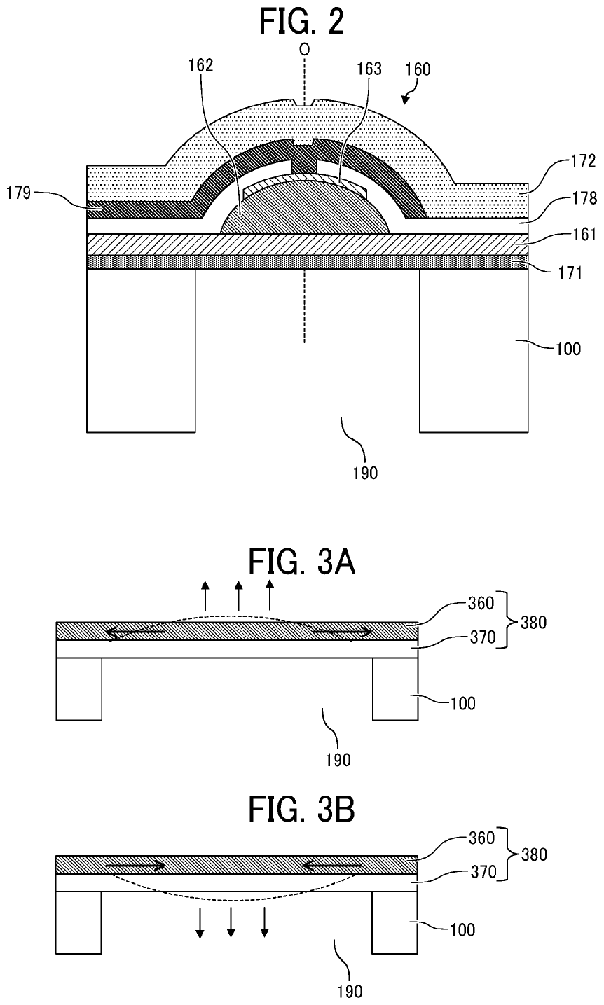

FIG. 2 is a diagram illustrating another example of the piezoelectric element 160 in the present embodiment.

In this example, the piezoelectric layer 162 is formed into a dome shape. In this example, an interlayer insulating layer 178 is provided on the upper side of the upper electrode layer 163. The second insulating film 172 also has a function of protecting a signal line 179. For example, the piezoelectric elements 160 are arranged in an array, and the respective piezoelectric elements 160 are electrically coupled to each other by the signal line 179. In this example, the central axis of the piezoelectric element 160 is indicated by O. The void 190 is, for example, a cylindrical opening opened in the silicon substrate 100.

In this manner, in the present embodiment, the shape and the like of the piezoelectric layer in the piezoelectric element can be appropriately changed. Also in the example illustrated in FIG. 2, the first insulating film 171 is thinner than the second insulating film 172.

FIGS. 3A to 5B are diagrams schematically illustrating vibration in the piezoelectric device. First, FIGS. 3A and 3B will be described. In the drawings, a piezoelectric element 360 and a base layer 370 are schematically illustrated, a diaphragm 380 includes the piezoelectric element 360 and the base layer 370, and the base layer 370 includes an insulating film. When a positive or negative voltage is applied between upper and lower electrodes of the piezoelectric element 360, a compressive stress and a tensile stress are generated in the piezoelectric element 360. The compressive stress and the tensile stress are generated in this manner, so that the diaphragm 380 of the substrate is bent up and down.

FIG. 3A schematically illustrates a case where the compressive stress is generated, and a broken line and arrows in the drawing schematically indicate a deformation direction of the diaphragm 380. FIG. 3B schematically illustrates a case where the tensile stress is generated. As illustrated in FIGS. 3A and 3B, when the base layer 370 is on a lower side of the piezoelectric element 360, the diaphragm 380 is deformed upward when the compressive stress is generated, and the diaphragm 380 is deformed downward when the tensile stress is generated.

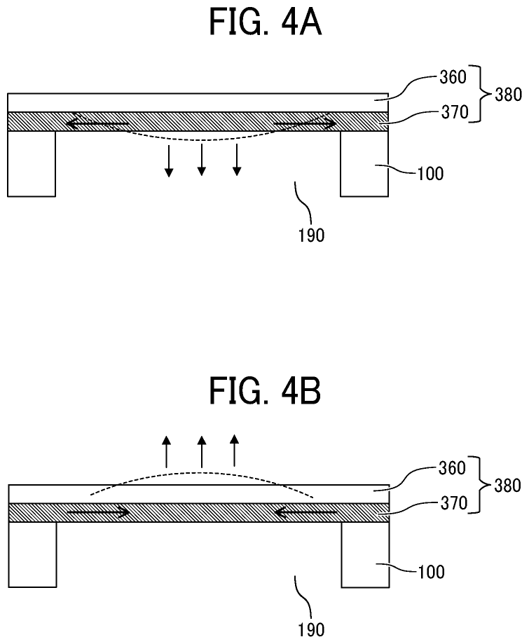

Next, FIGS. 4A and 4B will be described. In FIGS. 4A and 4B, unlike in FIGS. 3A and 3B, the base layer 370 is provided on an upper side of the piezoelectric element 360. FIG. 4A schematically illustrates a case where the compressive stress is generated, and FIG. 4B schematically illustrates a case where the tensile stress is generated. As illustrated in FIGS. 4A and 4B, when the base layer 370 is on the upper side of the piezoelectric element 360, the diaphragm 380 is deformed downward when the compressive stress is generated, and the diaphragm 380 is deformed upward when the tensile stress is generated.

That is, the diaphragm 380 in FIGS. 3A and 3B and 4A and 4B is deformed in opposed directions. The vibration system as illustrated in FIGS. 3A and 3B and 4A and 4B is also referred to as a diaphragm bent system and the like. The diaphragm bent system is a system in which a diaphragm (vibration region) is bent up and down by displacement of a contained piezoelectric element to be vibrated. In the present embodiment, such diaphragm bent system is adopted. In a case of the diaphragm bent system as in the present embodiment, a direction of vibration displacement changes depending on a positional relationship between the base layer 370 and the piezoelectric element 360 of the diaphragm 380.

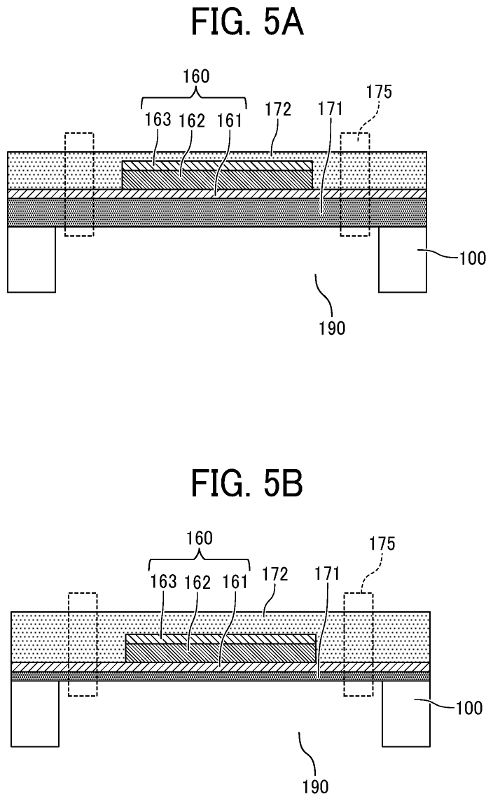

Next, FIGS. 5A and 5B will be described. FIGS. 5A and 5B illustrate a layer configuration of the piezoelectric element 160 in more detail than FIGS. 3A and 3B and 4A and 4B, and illustrate the first insulating film 171 and the second insulating film 172. In FIG. 5A, the first insulating film 171 is thicker than the second insulating film 172, which is considered similarly to a case where the base layer 370 is on the lower side of the piezoelectric element 360 as in FIGS. 4A and 4B. In FIG. 5B, the first insulating film 171 is thinner than the second insulating film 172, which is considered similarly to a case where the base layer 370 is on the upper side of the piezoelectric element 360 as in FIGS. 3A and 3B.

FIG. 5A illustrates an example in which the first insulating film 171 is thicker than the second insulating film 172, the example not included in the present embodiment. FIG. 5B illustrates an example in which the first insulating film 171 is thinner than the second insulating film 172, the example included in the present embodiment. The example illustrated in FIG. 5B corresponds to the example illustrated in FIG. 1. As described above, in the piezoelectric device according to the present embodiment, the second insulating film 172 (upper insulating film) is thicker than the first insulating film 171 (lower insulating film) unlike in the conventional manufacturing method.

The displacement portion 175 indicated by a broken line in the drawing is a portion that deforms more than other portions at the time of driving (at the time of bending). Configurations of the first insulating film 171, the piezoelectric element 160, the second insulating film 172, and the displacement portion 175 affect various vibration characteristics. Although not described in detail, it is designed in consideration of a film thickness, rigidity, an internal stress, various dimensions (width, length, shape, and the like), and the like of the first insulating film 171, the piezoelectric element 160, the second insulating film 172, and the displacement portion 175. It has been found that they significantly affect various vibration characteristics, and appropriate pre-design is required through simulation and short-loop experiment.

When the diaphragm is vibrated by the piezoelectric system, it is required to make one of the upper insulating film and the lower insulating film thick (thin). When they have the same thickness, it is not possible to vibrate. Therefore, in FIGS. 3A to 5B, one of the upper insulating film and the lower insulating film is made thick (thin).

### [Liquid Discharge Head]

The piezoelectric device of the present embodiment can be suitably applied to the liquid discharge head.

The liquid discharge head of the present embodiment is provided with the piezoelectric device of the present embodiment, and includes the through hole that penetrates the piezoelectric element 160 and communicates with the void 190. The void 190 is supplied with liquid, and the through hole is a nozzle hole (nozzle) that discharges the liquid. The piezoelectric element 160 is formed around the nozzle hole.

According to the present embodiment, it is possible to obtain the liquid discharge head including the CMOS element and the piezoelectric element on the same substrate and achieving both the CMOS operation and droplet discharge operation. The liquid discharge head of the present embodiment can secure various characteristics of the CMOS element, and can obtain piezoelectric performance (driving force) that enables discharge of droplets while maintaining the CMOS element operation.

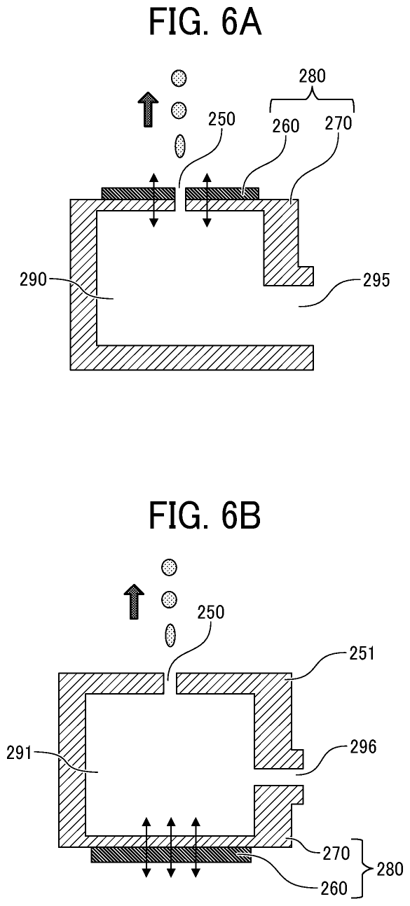

Before describing an example of the liquid discharge head of the present embodiment, a discharge system in the liquid discharge head will be described. FIGS. 6A and 6B are diagrams for explaining a discharge principle of a piezoelectric system liquid discharge head.

FIG. 6A is a schematic view for explaining a nozzle plate vibration system, and FIG. 6B is a schematic view for explaining a conventional discharge system that is generally and widely used.

In the example illustrated in FIG. 6A, a diaphragm 280 includes, for example, a piezoelectric element 260, a diaphragm base layer 270, and a nozzle 250. The piezoelectric element 260 is formed around the nozzle 250. The liquid (for example, ink) flows into an individual chamber 290 via an ink channel 295. When the piezoelectric element 260 is driven, the diaphragm 280 is displaced as indicated by arrows in the drawing, and the ink in the individual chamber 290 is discharged as droplets from the nozzle 250.

Since the diaphragm 280 includes the nozzle, this may be referred to as a nozzle plate and the like. In this manner, since the diaphragm including the nozzle (nozzle plate) vibrates to discharge the liquid, the discharge system in the example illustrated in FIG. 6A is referred to as the nozzle plate vibration system and the like.

In contrast, in the conventional discharge system illustrated in FIG. 6B, the diaphragm 280 includes the diaphragm base layer 270 and the piezoelectric element 260 on the diaphragm base layer 270, but the nozzle 250 is not formed. The individual pressure chamber 291 includes a nozzle plate 251 (nozzle plate) on which the nozzle 250 is formed and the diaphragm 280 opposed to the nozzle plate 251. The ink is introduced into the individual pressure chamber 291 via fluid resistance 296.

In the conventional discharge system, a voltage (drive voltage) is applied to the piezoelectric element 260 to vibrate the diaphragm 280 as indicated by arrows in the drawing, and the ink in the individual pressure chamber 291 is pressurized. Thus, the ink is discharged from the nozzle 250.

In the conventional discharge system, a large pressurizing force is required to discharge the ink, and the piezoelectric element is required to have high piezoelectric performance (high driving force). Although a bulk (solid) lead zirconate titanate (PZT) element has been widely used for the piezoelectric element so far, in recent years, piezoelectric performance of a thin film PZT has been improved, and the thin film PZT has been widely used. It has been recently found that a non-lead potassium sodium niobate (KNN) material exhibits high piezoelectric performance, and utilization thereof has started. A method of pressurizing the ink has a complicated discharge mechanism such as using pressure resonance, but a detailed description thereof is herein omitted.

Conventionally, the liquid discharge apparatus of the conventional discharge system illustrated in FIG. 6B has been widely used, but there are few examples in which the nozzle plate vibration system illustrated in FIG. 6A is put into practical use and put on the market. The reason for this is not clear, but it is considered that there are many problems in workability of bulk PZT, which has been often used conventionally, and there are many problems in mounting an electrode because a piezoelectric element using PZT is on a nozzle surface.

It is considered that the problems in workability of PZT can be solved by the recent practical application of the thin film PZT element, and the problems in mounting the electrode can be solved by applying an improved method of mounting the electrode of a thermal head. It has been found that, when the thin film PZT element and the improved method of mounting the electrodes of the thermal head are applied to the example illustrated in FIG. 6A, the droplets can be discharged even with a smaller driving force than in the example illustrated in FIG. 6B.

Specifically, for example, in the example illustrated in FIG. 6A, it has been confirmed that the ink can be discharged even if the thicknesses of the diaphragm base layer 270 and the piezoelectric element 260 are decreased, the rigidity of the diaphragm 280 is significantly reduced, and the drive voltage to the piezoelectric element 260 is reduced to a several tenth part as compared with the example illustrated in FIG. 6B. In other words, this indicates that even if the piezoelectric performance of the piezoelectric body is reduced to a several tenth part as compared with the conventional discharge system, the droplets can be discharged by the nozzle plate vibration system.

In the nozzle plate vibration system, since an inertia force of fluid in the vicinity of the nozzle can be used because the nozzle plate including the nozzle directly vibrates, it is considered that the ink can be discharged with a low driving force as compared with the conventional discharge system. The inventor of the present embodiment confirmed through simulations and demonstration experiments that droplets can be discharged even when the driving force of the diaphragm is reduced to about several tenth part of that of the conventional discharge system in the nozzle plate vibration system. However, there are still many unclear points in the discharge principle, and the detailed description thereof is herein omitted.

As described in the description of the piezoelectric device, it is necessary to appropriately contrive to form the CMOS element and the piezoelectric element on the same substrate, and the inventor of the present embodiment conducted intensive studies. The method of manufacturing the piezoelectric device of the present embodiment is different from the conventional manufacturing method in which the piezoelectric element is formed after the wiring layer for the CMOS element is formed. In the method of manufacturing the piezoelectric device according to the present embodiment, after the CMOS element is formed, the piezoelectric element is formed, and then the wiring layer is formed. By doing so, the CMOS element and the piezoelectric element can be formed on the same substrate, the CMOS operation can be performed, and the excellent piezoelectric characteristics can be obtained.

In contrast, it was found that, even when the piezoelectric device in which the CMOS element and the piezoelectric element are formed on the same substrate, the piezoelectric device that can perform the CMOS operation was applied to the liquid discharge head, an excellent droplet discharge operation could not be performed by the conventional discharge system. Therefore, intensive studies were conducted, and a condition was found that both a desired CMOS operation and the droplet discharge operation can be achieved by forming the CMOS element, then forming the piezoelectric element at formation temperature set in a predetermined range before forming the CMOS wiring, and combining the same with a nozzle plate vibration system. The content specifically studied is a relationship with the piezoelectric characteristics and a relationship with the droplet discharge operation in the nozzle plate vibration system with the formation temperature of the piezoelectric element as a parameter. This study result will be described in a manufacturing method, examples, and the like.

The liquid discharge head of the present embodiment includes the CMOS element and the piezoelectric element on the same substrate, and can achieve both the CMOS operation and the excellent droplet discharge operation.

According to the present embodiment, it is possible to obtain advantages of a thermal system while maintaining advantages of the piezoelectric system. In the piezoelectric system, advantages such as a high driving force (high viscosity, large droplet), a high degree of freedom in ink, and high driving durability are easily obtained, but it has been conventionally difficult to simultaneously obtain advantages of the thermal system such as small size, high density, and low cost. By implementing the liquid discharge head including the CMOS element and the piezoelectric element on the same substrate as in the present embodiment, the above-described advantages can be obtained by further adopting the nozzle plate vibration system.

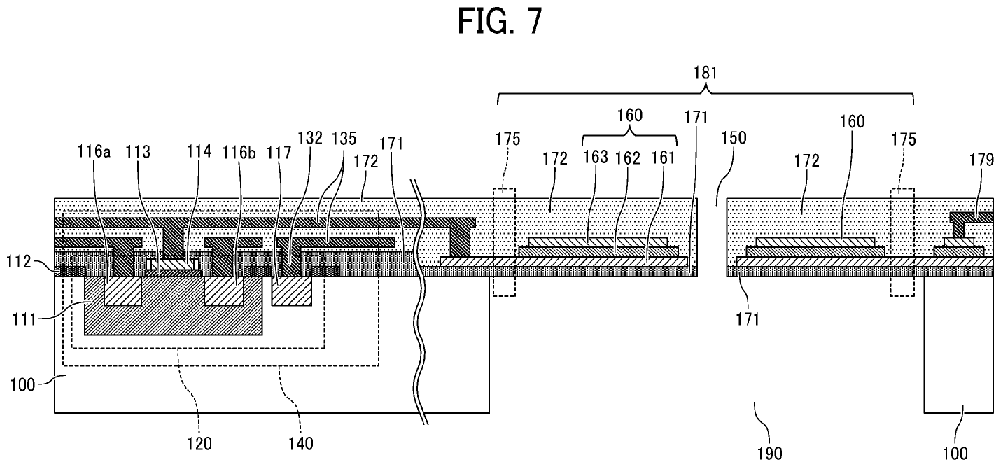

FIG. 7 is a diagram illustrating an example of the liquid discharge head according to the present embodiment. Here, differences from FIG. 1 will be mainly described.

In the present example, as illustrated in the drawing, the through hole that penetrates the piezoelectric element 160 and communicates with the void 190 is included, and the through hole is the nozzle hole 150 that discharges liquid. The void 190 to which the liquid is supplied may be referred to as a liquid chamber, an individual chamber, and the like.

The piezoelectric element 160 is formed around the nozzle hole 150. When the displacement portion 175 is deformed, the vibration region 181 vibrates. A portion including the first insulating film 171, the second insulating film 172, and the piezoelectric element 160 in the vibration region 181 may be referred to as the diaphragm or nozzle plate. In this example, when the piezoelectric element 160 is driven, the nozzle plate vibrates, and droplets are discharged from the nozzle hole 150. In this manner, the liquid discharge head of the present example discharges the droplets by the nozzle plate vibration system.

The diaphragm containing the piezoelectric element 160 is a portion that significantly affects the droplet discharge characteristics. The droplet discharge characteristics are affected not only by the characteristics (piezoelectric characteristics, rigidity, various dimensions, and the like) of the piezoelectric element 160 but also by the film thickness, material, and the like of the first insulating film 171 (lower insulating film) and the second insulating film 172 (upper insulating film).

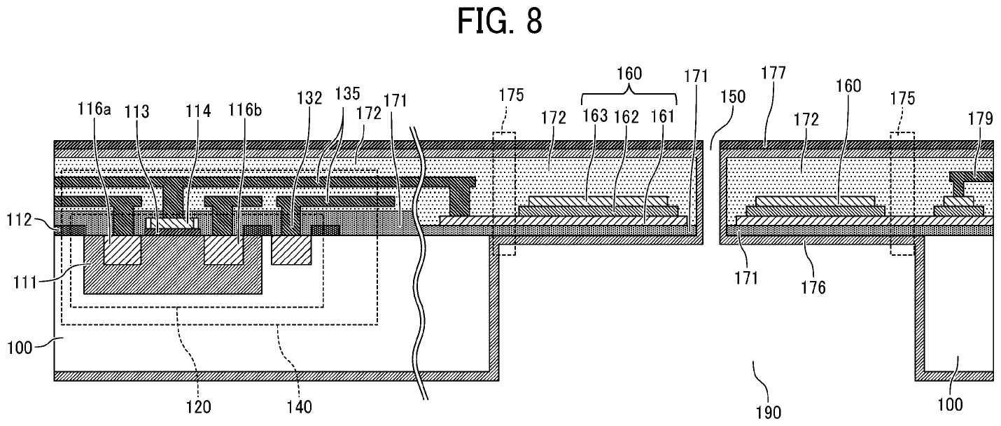

FIG. 8 is a diagram illustrating another example of the liquid discharge head of the present embodiment. In the example illustrated in FIG. 8, an ink liquid contact film 176 (liquid contact film) and a nozzle water-repellent film 177 (water-repellent film) are arranged in the example illustrated in FIG. 7. In the present example, the silicon substrate 100 includes the ink liquid contact film 176 at a site in contact with liquid, and includes the nozzle water-repellent film 177 on a surface on a side on which the liquid is discharged.

The ink liquid contact film 176 is provided at the site in contact with the liquid. The ink liquid contact film 176 is provided, for example, in the channel, and is provided, for example, on an inner wall of the void 190 (liquid chamber) or an inner wall of the nozzle hole 150. By including the ink liquid contact film 176, elution of various materials due to ink contact, deterioration in adhesion between the materials, and the like can be prevented.

As the ink liquid contact film 176, for example, a metal oxide film such as TaOx and HfOx having high liquid contact resistance (ink resistance) can be used. As the ink liquid contact film 176, in addition to the above, a laminated film or a mixed film of the above-described metal oxide film and the silicon oxide film (SiOx) can be used. In order to enable smooth ink introduction into the ink channel, a material having high lyophilic property (ink-philic property, hydrophilic property) is more appropriate, and using such laminated film or mixed film as the ink liquid contact film 176 enables smooth ink introduction. For the above-described reason, in the present example, a mixed film of Ta₂O₅ and SiO₂ is formed on an entire surface of the actuator using an atomic layer deposition (ALD) method.

In a case of the nozzle plate vibration system as in the present embodiment, it is not essential to make the void 190 a closed space, and there also is an advantage that the device configuration and the method are simplified. For example, as illustrated in FIG. 6B, in the conventional discharge system, it is required to provide the fluid resistance 296 in a path to the individual pressure chamber 291 (liquid chamber) to make the individual pressure chamber 291 (liquid chamber 291) a closed space. From this viewpoint, in a case of the nozzle plate vibration system as in the present embodiment, the device configuration and the method can be simplified.

In contrast, the closed space as in the conventional discharge system has an advantage that the ink introduction is facilitated using a capillary phenomenon. From this viewpoint, the nozzle plate vibration system might be disadvantageous in terms of ink introduction in some cases. In consideration of this, it might be preferable to use a lyophilic (ink-philic, hydrophilic) material as the ink liquid contact film 176.

In the present example, the nozzle water-repellent film 177 (water-repellent film) is provided on the surface on the side on which the liquid is discharged. By using the nozzle water-repellent film 177, water repellency of the surface on the droplet discharge side of the nozzle plate can be enhanced, and ink dischargeability is improved. By using the nozzle water-repellent film 177, ink retention and ink adhesion on the surface of the nozzle plate can be prevented.

As the nozzle water-repellent film 177, for example, a polymer material having high liquid repellent property (ink repellent property and water repellent property), such as perfluorodecyltrichlorosilane (FDTS) or fluorotetrahydrooctyldimethylchlorosilane (FOTS), can be used.

In this example, FOTS is uniformly formed on the surface of the nozzle plate using a (molecular vapor deposition) MVD method. There is a case where this film is formed on a portion other than the surface of the nozzle plate (for example, in the nozzle hole, in the ink liquid chamber), and measures for removing the same might be taken, but the detailed description thereof is omitted. Durability against a mechanical stress at the time of nozzle wiping (nozzle surface cleaning) is also required, so that it is also important to obtain strong adhesion with a base material.

As in the present example, the liquid discharge head using the ink liquid contact film 176 and the nozzle water-repellent film 177 has excellent ink filling property (introduction of ink into the ink channel) and excellent ink liquid contact durability. This also has stable and excellent ink discharge characteristics, and maintains cleanliness of the surface of the nozzle plate and has high durability. In this example, the liquid discharge head of a higher quality can be obtained.

### [Method of Manufacturing Piezoelectric Device and Method of Manufacturing Liquid Discharge Head]

Next, the method of manufacturing the piezoelectric device and a method of manufacturing the liquid discharge head of the present embodiment will be described. A method of manufacturing a piezoelectric device according to the present embodiment includes
a CMOS element forming step of forming a CMOS element on a substrate,
a piezoelectric element forming step of forming a piezoelectric element on the substrate;
a wiring layer forming step of forming a wiring layer of the CMOS element and a wiring layer of the piezoelectric element; and
a void forming step of forming a void in the substrate, wherein
the CMOS element and the piezoelectric element are formed on a same substrate,
at the CMOS element forming step or the piezoelectric element forming step, a first insulating film is formed in a region where the piezoelectric element is formed,
at the piezoelectric element forming step, a lower electrode layer, a piezoelectric layer, an
upper electrode layer, and a second insulating film are formed on the first insulating film,
at the void forming step, the void is formed on a side opposite to the piezoelectric layer across the lower electrode layer in the substrate, and
the CMOS element forming step, the piezoelectric element forming step, the wiring layer forming step, and the void forming step are performed in this order.

In the conventional manufacturing method, when the CMOS element and the piezoelectric element are formed on the same substrate, wiring (for example, metal wiring and interlayer insulating film) to the CMOS element has been damaged when forming the piezoelectric element, and the CMOS operation has not been normally performed. When the piezoelectric element is formed after the CMOS element is formed, it is considered to be required to form the piezoelectric element at the formation temperature of, for example, 500° C. or lower in order to avoid damage to the wiring to the CMOS element. However, it was found that, when the piezoelectric element was formed at such formation temperature, the piezoelectric characteristics were significantly deteriorated, and the droplet discharge operation could not be performed even by the nozzle plate vibration system.

In the present embodiment, after the CMOS element is formed on the substrate on which the nozzle hole for droplet discharge is formed, the piezoelectric element and the wiring are created in an appropriate order under an appropriate condition. As a result, it is possible to obtain the piezoelectric device including the CMOS element and the piezoelectric element on the same substrate and achieving both the CMOS operation and the excellent piezoelectric characteristics.

According to the present embodiment, it is possible to provide the liquid discharge head having advantages of a piezoelectric system such as high output (high viscosity, large droplets), high degree of freedom in ink, and high driving durability, and advantages of a thermal system such as small size, high density, and low cost.

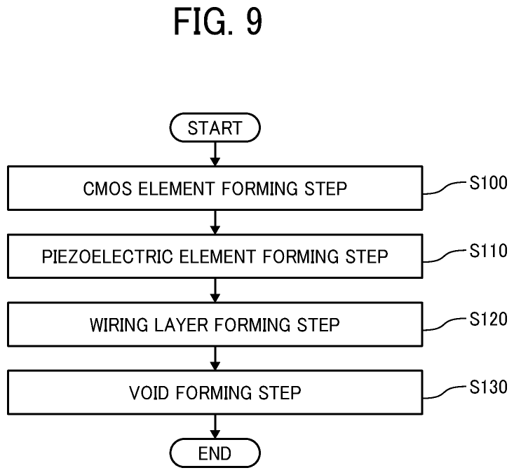

FIG. 9 is a flowchart for explaining an example of a method of manufacturing the piezoelectric device of the present embodiment. In this example, a CMOS element forming step (S100), a piezoelectric element forming step (S110), a wiring layer forming step (S120), and a void forming step (S130) are performed in this order. Other steps may be performed as necessary.

When the CMOS element and the piezoelectric element are formed on the same substrate, it is required to consider the viewpoint of step management to avoid contamination of a semiconductor manufacturing line with heavy metals, alkalis, and the like. Therefore, it is required to first form the CMOS element and then form the piezoelectric element. In consideration of the above, the CMOS element forming step is performed first, and the piezoelectric element forming step is performed later.

When the piezoelectric element is formed on the same substrate as the CMOS element, it is required to form the piezoelectric element at temperature lower than the formation temperature of the CMOS element in order to secure various characteristics of the CMOS element. The piezoelectric element such as a PZT thin film element is usually formed at temperature of about 850° C. When this is formed at temperature lower than the formation temperature of the CMOS element, for example, 750° C., the piezoelectric characteristics (piezoelectric constant, piezoelectric displacement amount, and driving force) are significantly deteriorated.

In general, when manufacturing a CMOS integrated functional device, the wiring to the CMOS element is formed, and then a portion of the functional device is manufactured. However, the wiring to the CMOS is usually manufactured at temperature of about 300° C. to 400° C. in many cases, and is at most about 500° C. or lower. Therefore, when the piezoelectric element is formed after the wiring to the CMOS element is formed, the wiring is damaged, and the functional device cannot perform the CMOS operation.

Although it varies depending on the material of the wiring to the CMOS element, the material of the interlayer insulating film, and the manufacturing method thereof, the wiring to the CMOS element is usually manufactured at around 350° C. in many cases. Therefore, when the piezoelectric element is formed after the wiring is formed, the piezoelectric element needs to be subjected to heat treatment with a light load of about 500° C. or lower in order to prevent elution or disconnection of the wiring, cracking or dielectric breakdown of the interlayer insulating film, and the like. However, when the piezoelectric element is manufactured at low temperature, the excellent piezoelectric characteristics cannot be obtained.

Therefore, in the present embodiment, by performing the wiring layer forming step after the piezoelectric element forming step, the formation temperature region of the piezoelectric body can be made higher than the formation temperature at the wiring layer forming step and the step can be performed in a temperature region lower than that at the CMOS element forming step. For this reason, the wiring layer forming step is performed after the piezoelectric element forming step.

In the manufacturing method of the present embodiment, it is preferable to appropriately adjust the relationship between the formation temperature at the CMOS element forming step and the formation temperature at the piezoelectric element forming step.

A design rule and a manufacturing process of the CMOS element significantly differ depending on a requirement of a desired circuit. A final high-temperature heating step (for example, heat treatment for impurity diffusion) in the CMOS operation, particularly the CMOS element forming step that affects the threshold voltage, is conventionally performed with a heat history at 900° C. for 30 minutes or longer in many cases. After the CMOS element is formed, if a heat history of the same degree or greater than this is applied, the CMOS element is difficult to maintain the various characteristics. For example, the threshold voltage of the CMOS element significantly deviates from a specification value, and the circuit no longer operates. In consideration of the above, the formation temperature of the piezoelectric element is also studied.

For example, at the piezoelectric element forming step, it is preferable to form the piezoelectric element at temperature lower than the temperature of the final high-temperature heat treatment out of the high-temperature heat treatments for forming the CMOS element. By doing so, deterioration in CMOS element can be prevented.

The final high-temperature heat treatment out of the high-temperature heat treatments for forming the CMOS element can be appropriately selected, and examples thereof include, for example, the final high-temperature heat treatment that affects a CMOS characteristic value (threshold voltage and the like) and the final high-temperature heat treatment that adjusts the CMOS characteristic value (threshold voltage and the like). In addition, the final high-temperature heat treatment out of the high-temperature heat treatments for forming the CMOS element includes a heat treatment for impurity diffusion when forming NMOS or PMOS source electrode and drain electrode in the CMOS element.

Examples of the final high-temperature heat treatment out of the high-temperature heat treatments for forming the CMOS element include, for example, a heat treatment for impurity diffusion when forming NMOS or PMOS source electrode and drain electrode in the CMOS element. Therefore, in the piezoelectric element forming step, it is preferable to form the piezoelectric element at temperature lower than the temperature of the heat treatment for impurity diffusion at the time of forming the NMOS or PMOS source electrode and drain electrode in the CMOS element. By doing so, deterioration in CMOS element can be prevented.

At the piezoelectric element forming step, it is more preferable to form the piezoelectric element at temperature lower by 100° C. or more than the temperature of the final high-temperature heat treatment (for example, the heat treatment for impurity diffusion) performed at the CMOS element forming step. In this case, it is possible to further reliably prevent the operation of the CMOS element from becoming defective.

The CMOS element is usually formed at 900° C. or higher in many cases. When the same degree of heat history is added after the CMOS is formed, CMOS characteristics change (deteriorate). A particularly large influence is a change in threshold voltage. As a result of studies, it was found that, when the piezoelectric element was formed at 750° C. or lower after the CMOS element was formed, this threshold voltage hardly changed. In a case of temperature lower by about 100° C. than the formation temperature of the CMOS element, for example, 800° C., the threshold voltage slightly changed, but it was also found that the operation was generally performed.

For this reason, as described above, it is more preferable to form the piezoelectric element at temperature lower by 100° C. or more than the temperature of the final high-temperature heat treatment (for example, the heat treatment for impurity diffusion) performed at the CMOS element forming step, it is more preferable to form the piezoelectric element at 750° C. or lower, and it is still more preferable to form the piezoelectric element at temperature of 800° C. or lower. By doing so, the CMOS operation can be prevented from becoming defective.

At the piezoelectric element forming step, it is more preferable to form the piezoelectric element at temperature of 500° C. or higher. In this case, it is possible to prevent the piezoelectric characteristics from becoming defective. At the piezoelectric element forming step, it is still more preferable to form the piezoelectric element at temperature of 500° C. or higher and 800° C. or lower. In this case, the CMOS operation can be prevented from being defective, and the piezoelectric characteristics can be prevented from being defective.

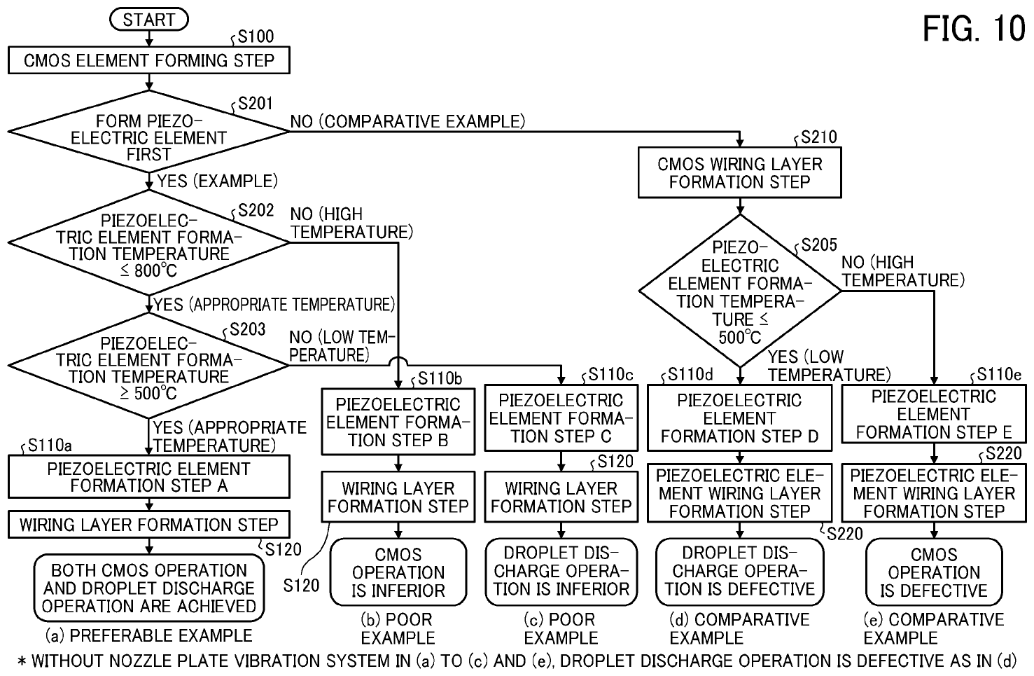

FIG. 10 illustrates an example of a flowchart for explaining that various characteristics differ depending on the conditions of the manufacturing method. In this flowchart, a case where the liquid discharge head is manufactured is assumed, and an example the formation temperature of the piezoelectric element is also described.

First, the CMOS element forming step is performed (S100). As a next step, there is an option of forming the piezoelectric element before or after the wiring layer (S201). When the piezoelectric element is formed before the wiring layer, this is an example included in the present embodiment.

When the piezoelectric element is formed before the wiring layer, the formation temperature of the piezoelectric element is appropriately adjusted. When the formation temperature of the piezoelectric element is 800° C. or lower (YES at S202) and 500° C. or higher (YES at S203), the liquid discharge head obtained by a piezoelectric element forming step A (S110a) and a wiring layer forming step (S120) can achieve both the CMOS operation and the droplet discharge operation at a high level. This is (a) a preferred example.

When the formation temperature of the piezoelectric element is higher than 800° C. (No at S202), the liquid discharge head obtained by a piezoelectric element forming step B (S110b) and the wiring layer forming step (S120) can achieve both the CMOS operation and the droplet discharge operation, but the CMOS operation is deteriorated. This is (b) a poor example. When the formation temperature of the piezoelectric element is higher than 800° C., it is considered that the CMOS element is affected.

When the formation temperature of the piezoelectric element is lower than 500° C. (No at S203), the liquid discharge head obtained by a piezoelectric element forming step C (S110c) and the wiring layer forming step (S120) can achieve both the CMOS operation and the droplet discharge operation, but the liquid discharge operation is deteriorated. This is (c) a poor example. When the formation temperature of the piezoelectric element is lower than 500° C., it is considered that the piezoelectric element cannot be sufficiently heated, and the droplet discharge operation is affected.

In a case of NO at S201, that is, when the wiring layer is formed before the piezoelectric element as in the conventional technology, this is a comparative example not included in the present embodiment. In this case, after the CMOS element is formed, the wiring to the CMOS element is formed (S210). Thereafter, the piezoelectric element is formed; when the formation temperature of the piezoelectric element is 500° C. or lower (YES at S205), the liquid discharge head obtained by a piezoelectric element forming step D (S110d) and a wiring layer forming step of the piezoelectric element (S220) has a defective droplet discharge operation (d). This is because the formation temperature of the piezoelectric element is low, so that the piezoelectric element that can obtain the excellent droplet discharge operation cannot be formed.

In a case of NO at S201, when the formation temperature of the piezoelectric element is higher than 500° C. (in a case of NO at S205), the CMOS operation of the liquid discharge head obtained by a piezoelectric element forming step E (S110e) and the wiring layer forming step of the piezoelectric element (S220) is defective (e). This is because the formation temperature of the piezoelectric element is high, so that the CMOS element is deteriorated.

In the drawings, the piezoelectric element forming steps A to E perform the same process except that the formation temperature of the piezoelectric element is different. At the wiring layer forming step (S120) in the drawing, wiring to the CMOS element and wiring of the piezoelectric element are formed.

In the manufacturing method of the present embodiment, the first insulating film 171 is formed in a region where the piezoelectric element 160 is formed, and the lower electrode layer 161, the piezoelectric layer 162, the upper electrode layer 163, and the second insulating film 172 are formed on the first insulating film 171. As described above, since the CMOS element forming step, the piezoelectric element forming step, the wiring layer forming step, and the void forming step are performed in this order, the thickness of the first insulating film 171 (lower insulating film) under the piezoelectric layer 162 is thinner than the thickness of the second insulating film 172 (upper insulating film) above the piezoelectric layer 162.

The step of forming the first insulating film 171 may be included in the CMOS element forming step or the piezoelectric element forming step. In addition, the step of forming the first insulating film 171 may be separated as an insulating film forming step and the like. The step of forming the second insulating film 172 is herein included in the piezoelectric element forming step, but there is no limitation, and the step of forming the second insulating film 172 may be separated as an insulating film forming step or the like.

At the piezoelectric element forming step, a method of forming the piezoelectric layer can be appropriately selected, and examples thereof include, for example, a sol-gel method, a sputtering method, and a chemical vapor deposition (CVD) method.

For example, when a PZT piezoelectric element is formed by the sol-gel method, this is usually formed by sintering at temperature of about 850° C., but when this is formed at 750° C. or lower, piezoelectric characteristics might be deteriorated in some cases. However, in a case of the nozzle plate vibration system, sufficient droplet discharge characteristics can be obtained. Even in a case of forming by the sputtering method or the CVD method, when the formation temperature is lowered, deterioration in piezoelectric characteristics is expected; however, in a case of the nozzle plate vibration system, sufficient droplet discharge characteristics are obtained.

The method of manufacturing the piezoelectric device according to the present embodiment may include a step of forming the through hole that penetrates the piezoelectric element 160 and communicates with the void 190. The step of forming the through hole can be performed, for example, at the void forming step. The formed through hole can be made the nozzle hole 150 in a case where the piezoelectric device is applied to the liquid discharge head.

By forming the nozzle hole 150 that penetrates the piezoelectric element 160, the piezoelectric element 160 is formed around the nozzle hole 150. As a result, the nozzle plate vibration system liquid discharge head can be obtained.

After the void forming step, a liquid contact film and water-repellent film forming step of forming a liquid contact film at a site in contact with the liquid of the substrate, and a water-repellent film on a surface on a side on which the liquid is discharged may be performed. As a result, the liquid discharge head illustrated in FIG. 8 is obtained. By performing the liquid contact film and water-repellent film forming step, it is possible to prevent elution of various materials due to ink contact, deterioration in adhesion between the materials, and the like, to enhance the water repellency of the surface on the droplet discharge side of the nozzle plate, and to obtain advantages such as improvement in ink dischargeability.

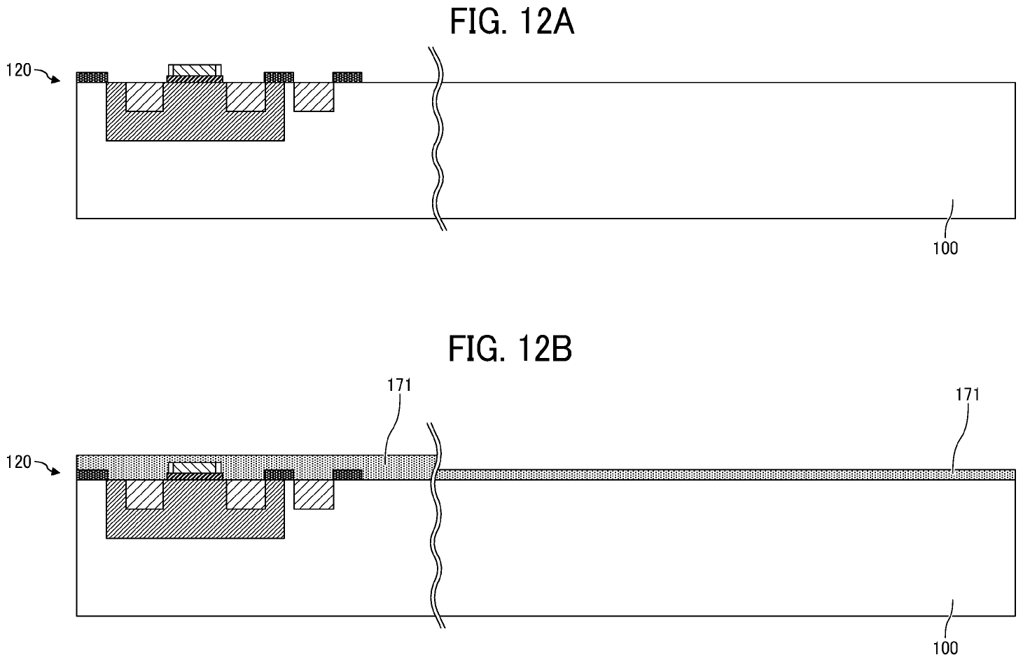

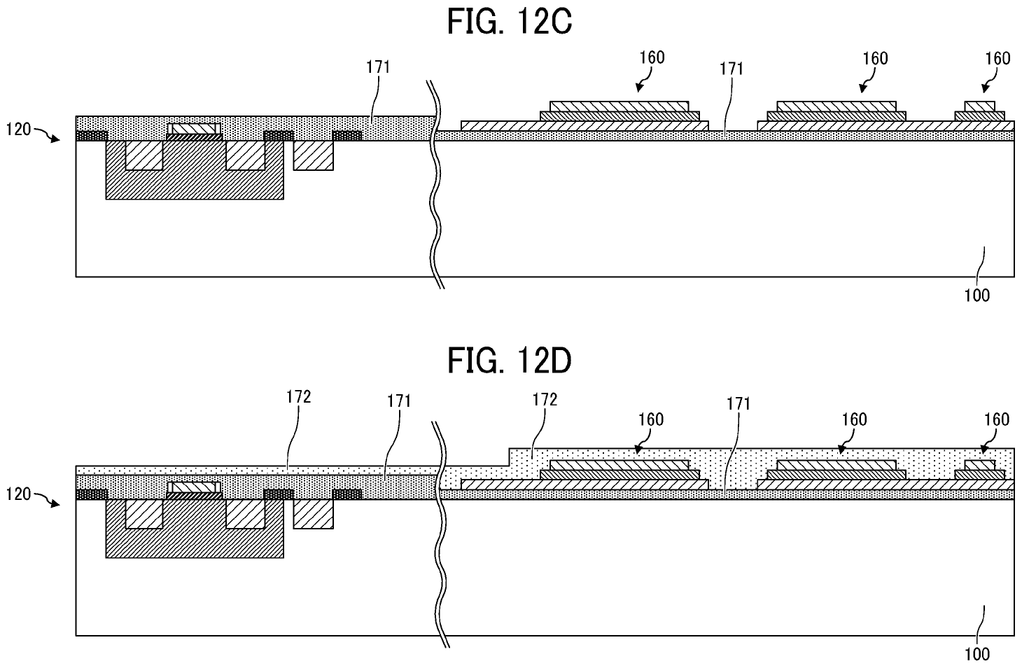

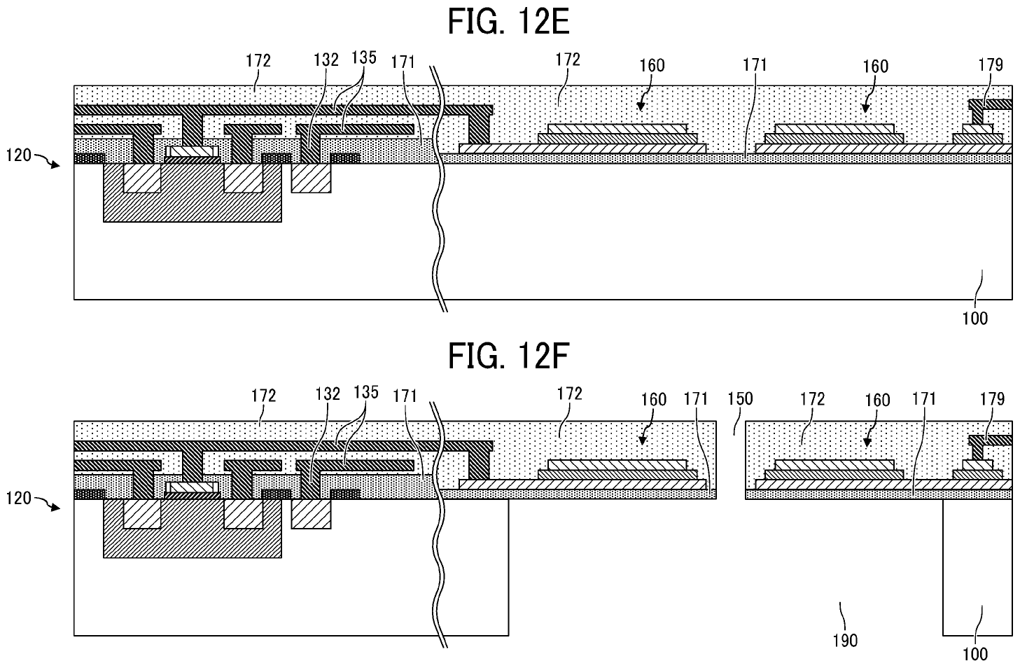

Example of Method of Manufacturing Piezoelectric Device and Method of Manufacturing Liquid Discharge Head Hereinafter, an example of the method of manufacturing the piezoelectric device and the method of manufacturing the liquid discharge head will be described with reference to FIGS. 11A to 11H and 12A to 12F.

FIGS. 11A to 11H are schematic views for explaining an example of a method of manufacturing the CMOS element. The example herein illustrated is a general manufacturing method, and in the present embodiment, the CMOS element can be formed using the general manufacturing method.

First, an active region in which the CMOS element is arranged is formed. FIGS. 11A and 11B illustrate a step of forming the N well 111, the field oxide film 112, and the gate oxide film 113 on the silicon substrate 100. The field oxide film 112 is the element isolation oxide film. In some cases, the P well may be formed in place of the N well 111.

The CMOS is formed of the combination of the NMOS and PMOS, but only the PMOS is illustrated in the drawing, and that related to the NMOS is omitted for convenience. This step is not particularly limited, but is performed with a heat history at about 900° C. or higher, for example, and is usually performed at 1000° C. or higher in many cases.

FIG. 11C illustrates a step of performing low-concentration impurity ion implantation for adjusting a threshold voltage of each of the PMOS and the NMOS. By performing the low-concentration impurity ion implantation, a channel doped region 108 is formed. Arrows in the drawing schematically indicate implantation of impurities. The channel doped region 108 is illustrated as a low-concentration impurity ion implantation region.

FIG. 11D illustrates a step of forming a gate electrode 104. The gate electrode 104 is formed, for example, by appropriately performing film formation, photolithography, etching, and the like. Here, these detailed steps are omitted.

FIG. 11E illustrates a step of forming the sidewall 115. The gate oxide film 113 is formed in a desired region.

FIG. 11F illustrates a step of performing high-concentration impurity ion implantation into a source region 106, a gate electrode region 104a, and a substrate electrode region 107. Arrows in the drawing schematically indicate implantation of impurities. The source region 106, the gate electrode region 104a, and the substrate electrode region 107 are illustrated as the impurity ion implantation regions. The channel doped region 108b is illustrated as a low-concentration impurity diffusion region.

FIG. 11G illustrates a step of performing thermal diffusion of the high-concentration impurities implanted in FIG. 11F and activation treatment (heat treatment for impurity diffusion). This step is the final heat treatment step when the CMOS element is formed. The channel doped region 108c is illustrated as a low-concentration impurity diffusion region.

Therefore, important CMOS characteristics (CMOS operation) such as the threshold voltage are designed in consideration of the heat history up to the step of FIG. 11G, and matching of process conditions is performed. These steps require a heat history of, for example, about 800° C. or higher, and are performed at about 900° C. in many cases. The heat treatment for impurity diffusion performed in FIG. 11G needs to be particularly noted. When the piezoelectric element is formed after the CMOS element is formed, it is preferable to form the piezoelectric element at temperature lower than the temperature at the final heat treatment step in order not to affect various characteristics of the CMOS element. The heat treatment in the formation of the piezoelectric element is preferably performed at temperature lower than the temperature of the heat treatment for impurity diffusion performed in FIG. 11G.

FIG. 11H illustrates a step of forming a layer serving as both the insulating interlayer film and a protective film after forming the CMOS element, and this layer is the first insulating film 171. The step of forming the first insulating film 171 may be included in the CMOS element forming step or the piezoelectric element forming step. Wiring to the CMOS element is performed in FIG. 12C described later.

As the first insulating film 171, a silicon oxide film by a CVD method is generally used. A silicon nitride film having high moisture resistance is also often used as an alternative layer or an additional layer. In the present embodiment, there is no limitation, and other examples can be used as appropriate.

The gate electrode 114 is illustrated as an activated impurity diffusion region. The channel region 118 is subjected to threshold voltage matching.

FIG. 12A is a diagram illustrating a state in which FIG. 11G is performed, and FIG. 11B is a diagram illustrating a state in which FIG. 11H is performed. Here, this is illustrated as the CMOS element 120, and details of each unit are the same as the contents illustrated in FIG. 1 and the like.

In FIG. 12B, the first insulating film 171 is illustrated, and the first insulating film 171 is also formed in a region where the piezoelectric element 160 is formed. The first insulating film 171 is a protective insulating film of the CMOS element and also serves as a lower insulating film of the piezoelectric element 160. Therefore, the first insulating film 171 is formed with a film thickness and rigidity designed in accordance with target vibration characteristics.

As the first insulating film 171, for example, a laminated film of a silicon oxide film and a silicon nitride film can be used. In the present embodiment, since the configuration of the insulating film can be appropriately selected, there is no limitation, and is illustrated in a simplified manner in the drawings.

FIG. 12C illustrates a step of forming the piezoelectric element 160 (piezoelectric body forming step), the diagrams illustrating a state in which the piezoelectric element 160 is formed. At the piezoelectric element forming step, for example, the lower electrode layer 161, the piezoelectric layer 162, and the upper electrode layer 163 are sequentially formed, and then photolithography and patterning are sequentially performed. Since the detailed steps of film formation and lowering are different depending on a layout pattern, a process concept, and the like of the piezoelectric element, there is no limitation to this example.

FIG. 12D illustrates a step of forming the second insulating film 172. The second insulating film 172 serves as a protective insulating film of the piezoelectric element 160 and also serves as an interlayer insulating film on the CMOS element. In the state illustrated in FIG. 12D, the second insulating film 172 is a first layer of interlayer insulating film on the CMOS element together with the previously formed first insulating film 171.

As the second insulating film 172, for example, a silicon oxide film can be used, but there is no limitation. The first insulating film 171 may be referred to as a lower insulating film because this is provided on a lower side of the piezoelectric element 160, and the second insulating film 172 may be referred to as an upper insulating film because this is provided on an upper side of the piezoelectric element 160.

FIG. 12E is a diagram illustrating a step of forming wiring (wiring layer forming step), a state in which the wiring is formed. At this step, processing of a through hole, formation and processing of a first metal layer, formation of an interlayer insulating film layer, processing of a through hole, formation and processing of a second metal layer, and formation of an interlayer insulating film layer were performed in this order. For example, the contact hole 132, the first layer of metal wiring (metal 1), the insulating interlayer film (interlayer film 1), the through hole, the second layer of metal wiring (metal 2), . . . , the insulating interlayer film (interlayer film n), the through hole, the n-th layer of metal wiring (metal n), and the like are sequentially formed. The electrical contact to the gate electrode 114, the source electrode 116a, the drain electrode 116b, and the substrate electrode 117 can be obtained by the contact hole 132, and the electrical contact between the metal wiring and the metal wiring can be obtained by the through hole.

In this example, the metal wiring 135 includes two layers, but the present embodiment is not limited thereto. An appropriate CMOS process design rule may be appropriately applied to the number of layers of wiring and the process according to a specification of a desired CMOS component. In this example, the laminated film of the silicon oxide film and the silicon nitride film is used as the uppermost interlayer insulating film.

As described above, the CMOS element and the piezoelectric element can be formed on the same substrate. In the state illustrated in FIG. 12E, the void forming step is performed to form the void 190, so that the piezoelectric device of this example can be manufactured.

The second insulating film 172 is the upper insulating film on the upper side of the piezoelectric element 160. The second insulating film 172 may have a laminated structure. For example, when the protective insulating film of the piezoelectric element and the interlayer insulating film are made of different materials, it can be said that the second insulating film 172 has the laminated structure. In this case, the second insulating film 172 includes the protective insulating film of the piezoelectric element and the interlayer insulating film.

The diaphragm (vibration region 181) is formed of, for example, the first insulating film 171, the piezoelectric element 160, and the second insulating film 172. The diaphragm may further include a resin film (nozzle water-repellent film, ink liquid-repellent film, and the like) and the like thereon. In order to obtain desired vibration characteristics, the film thickness, rigidity, film stress, dimensions (for example, the width of the diaphragm and the like) and the like of each layer are preferably formed precisely in advance to be designed and manufactured.

FIG. 12F is a diagram illustrating a state in which the nozzle hole 150 and the void 190 are formed. In this manner, the liquid discharge head of the present example can be manufactured. This state corresponds to completion of the CMOS integrated piezoelectric element actuator. The liquid discharge apparatus can be obtained by attaching an ink introduction frame, an ink delivery system, and the like, for example, to this.

### [Liquid Discharge Device and Liquid Discharge Apparatus]

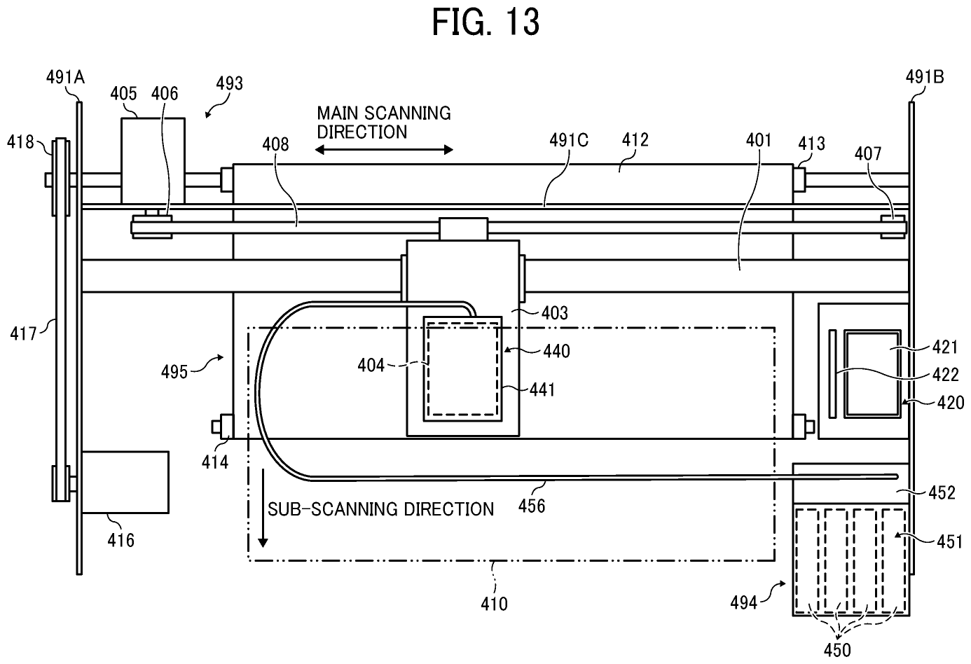

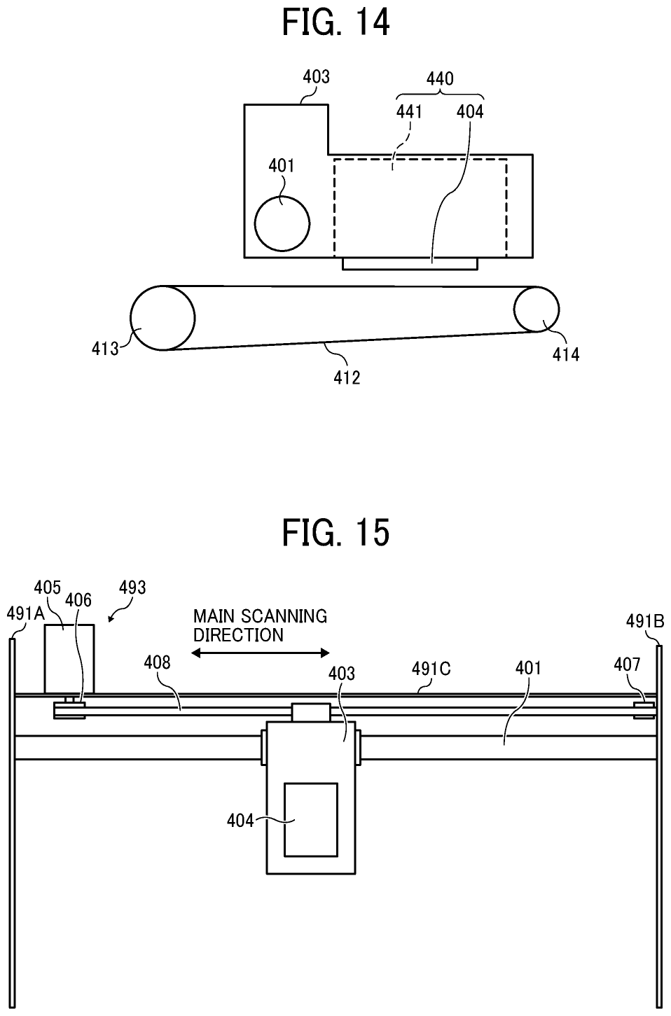

Next, a liquid discharge device and a liquid discharge apparatus (liquid discharge apparatus) according to the present embodiment will be described. An example of the liquid discharge apparatus according to the present embodiment will be described with reference to FIGS. 13 and 14. FIG. 13 is a plan view of a substantial part of the liquid discharge apparatus. FIG. 14 is a side view of the substantial part of the liquid discharge apparatus.

The liquid discharge apparatus is a serial type apparatus, and a carriage 403 reciprocally moves in a main scanning direction by a main scan moving unit 493. The main scan moving unit 493 includes a guide 401, a main scan motor 405, a timing belt 408, and the like. The guide 401 is bridged between a left side plate 491A and a right side plate 491B to moveably hold the carriage 403. The main scan motor 405 reciprocally moves the carriage 403 in the main scanning direction via the timing belt 408 bridged between a drive pulley 406 and a driven pulley 407.

The carriage 403 mounts the liquid discharge device 440. A head 404 according to the present embodiment and a head tank 441 form the liquid discharge device 440 as a single unit. The head 404 of the liquid discharge device 440 discharges liquid of each color, for example, yellow (Y), cyan (C), magenta (M), and black (K). The head 404 includes a nozzle array including multiple nozzles 11 arrayed in row in a sub scanning direction perpendicular to the main scanning direction. The head 404 is mounted to the carriage 403 so that ink droplets are discharged downward.

The liquids stored in liquid cartridges 450 are supplied to the head tank 441 by a supply unit 494 to supply the liquids stored outside the head 404 to the head 404.

The supply unit 494 includes a cartridge holder 451 serving as a filling part to mount the liquid cartridges 450, a tube 456, a liquid feeder 452 including a liquid feed pump, and the like. The liquid cartridge 450 is detachably attached to the cartridge holder 451. The liquid is fed from the liquid cartridge 450 to the head tank 441 by the liquid feeder 452 via the tube 456.

The liquid discharge apparatus includes a conveyor 495 to convey a sheet 410. The conveyor 495 includes a conveyance belt 412 as a conveyor and a sub scan motor 416 to drive the conveyance belt 412.

The conveyance belt 412 attracts the sheet 410 and conveys the sheet 410 to a position facing the head 404. The conveyance belt 412 is an endless belt stretched between a conveyance roller 413 and a tension roller 414. Attraction of the sheet 410 to the conveyance belt 412 may be applied by electrostatic adsorption, air suction, or the like.

The conveyance belt 412 rotates in the sub scanning direction as the conveyance roller 413 is rotationally driven by the sub scan motor 416 via the timing belt 417 and the timing pulley 418.

At one side in the main scanning direction of the carriage 403, a maintenance unit 420 to maintain the head 404 in good condition is disposed on a lateral side of the conveyance belt 412.

The maintenance unit 420 includes, for example, a cap 421 to cap a nozzle face of the head 404 and a wiper 422 to wipe the nozzle face. The nozzle face is a surface of the head 404 on which the multiple nozzles 11 are formed.

The main scan moving unit 493, the supply unit 494, the maintenance unit 420, and the conveyor 495 are mounted to a housing that includes the side plate 491A, the side plate 491B, and a rear-side plate 491C.

In the liquid discharge apparatus thus configured, the sheet 410 is conveyed on and attracted to the conveyance belt 412 and is conveyed in the sub scanning direction by the cyclic rotation of the conveyance belt 412.

The head 404 is driven in response to image signals while the carriage 403 moves in the main scanning direction, to discharge a liquid to the sheet 410 stopped, thus forming an image on the sheet 410.

In this manner, since this apparatus includes the liquid discharge head according to the present embodiment, a high-quality image can be stably formed.

Next, another example of the liquid discharge device 440 according to the present embodiment is described with reference to FIG. 15. FIG. 15 is a plan view of a substantial part of another example of the liquid discharge device 440.

The liquid discharge device 440 includes a housing, the main scan moving unit 493, the carriage 403, and the head 404 among components of the liquid discharge apparatus. The side plate 491A, the side plate 491B, and the rear-side plate 491C configure the housing.

The liquid discharge device 440 may be configured to further attach at least one of the above-described maintenance unit 420 and the supply unit 494 to, for example, the side plate 491B of the liquid discharge device 440.

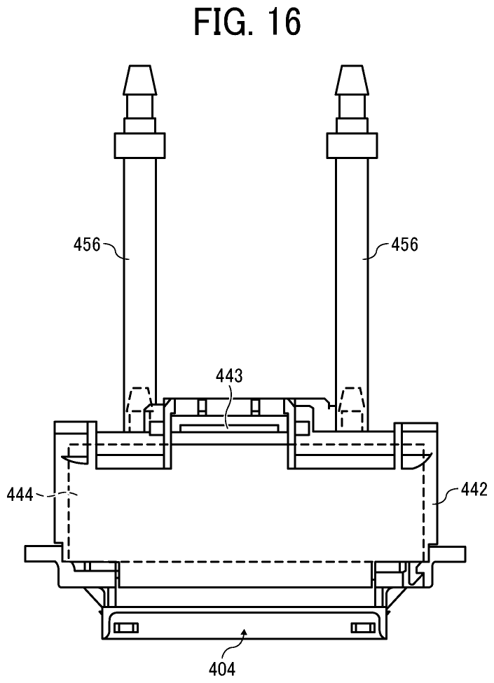

Next, still another example of the liquid discharge device 440 according to the present embodiment is described with reference to FIG. 16. FIG. 16 is a front view of still another example of the liquid discharge device 440.

The liquid discharge device 440 includes the head 404 to which a channel part 444 is attached and a tube 456 connected to the channel part 444.

The channel part 444 is disposed inside a cover 442. Instead of the channel part 444, the liquid discharge device 440 may include the head tank 441. A connector 443 electrically connected with the head 404 is provided on an upper part of the channel part 444.

In the above-described embodiments, the “liquid discharge apparatus” includes the head or the liquid discharge device and drives the head to discharge a liquid. The liquid discharge apparatus may be, for example, an apparatus capable of discharging a liquid to a material to which liquid can adhere or an apparatus to discharge liquid toward gas or into liquid.

The liquid discharge apparatus may include devices to feed, convey, and eject the material on which liquid can adhere. The liquid discharge apparatus may further include a pretreatment apparatus to coat a treatment liquid onto the material, and a post-treatment apparatus to coat a treatment liquid onto the material, onto which the liquid has been discharged.

The “liquid discharge apparatus” may be, for example, an image forming apparatus to form an image on a sheet by discharging ink, or a three-dimensional fabrication apparatus to discharge a fabrication liquid to a powder layer in which powder material is formed in layers to form a three-dimensional fabrication object.

The liquid discharge apparatus is not limited to an apparatus to discharge liquid to visualize meaningful images, such as letters or figures. For example, the liquid discharge apparatus may be an apparatus to form meaningless images, such as meaningless patterns, or fabricate three-dimensional images.

The above-described term “material onto which liquid can adhere” represents a material on which liquid is at least temporarily adhered, a material on which liquid is adhered and fixed, or a material into which liquid is adhered to permeate. Examples of the “material on which liquid can adhere” include recording media, such as paper sheet, recording paper, recording sheet of paper, film, and cloth, electronic component, such as electronic substrate and piezoelectric element, and media, such as powder layer, organ model, and testing cell. The “material on which liquid can adhere” includes any material on which liquid can adhere, unless particularly limited.

Examples of the “material on which liquid can adhere” include any materials on which liquid can adhere even temporarily, such as paper, thread, fiber, fabric, leather, metal, plastic, glass, wood, ceramic, construction materials (e.g., wallpaper or floor material), and cloth textile.

Examples of the “liquid” include ink, treatment liquid, DNA sample, resist, pattern material, binder, fabrication liquid, and solution or liquid dispersion containing amino acid, protein, or calcium.

The “liquid discharge apparatus” may be an apparatus to relatively move the head and a material on which liquid can adhere. However, the liquid discharge apparatus is not limited to such an apparatus. For example, the liquid discharge apparatus may be a serial head apparatus that moves the head or a line head apparatus that does not move the head.

Examples of the “liquid discharge apparatus” further include a treatment liquid coating apparatus to discharge a treatment liquid to a sheet to coat the treatment liquid on the surface of the sheet to reform the sheet surface and an injection granulation apparatus in which a composition liquid including raw materials dispersed in a solution is injected through nozzles to granulate fine particles of the raw materials.

The “liquid discharge device” is an assembly of parts relating to liquid discharge. The term “liquid discharge device” represents a structure including the head and a functional part(s) or mechanism combined to the head to form a single unit. For example, the “liquid discharge device” includes a combination of the head with at least one of a head tank, a carriage, a supply unit, a maintenance unit, and a main scan moving unit to form a single unit.

Examples of the “single unit” include a combination in which the head and one or more functional parts and units are secured to each other through, e.g., fastening, bonding, or engaging, and a combination in which one of the head and the functional parts and units is movably held by another. The head may be detachably attached to the functional part(s) or unit(s) each other.

For example, as a liquid discharge device 440, there is a liquid discharge device in which the head 404 and the head tank 441 form a single unit, as in the liquid discharge device 440 illustrated in FIG. 14. Alternatively, the head and the head tank coupled (connected) with a tube or the like may form the liquid discharge device as a single unit. A unit including a filter may be added at a position between the head tank and the head of the liquid discharge device.

In another example, the head and the carriage may form the liquid discharge device as a single unit.

In still another example, the liquid discharge device includes the head movably held by a guide that forms part of a main scan moving unit, so that the head and the main scan moving unit form a single unit. Like the liquid discharge device 440 illustrated in FIG. 15, the head 404, the carriage 403, and the main scan moving unit 493 may form the liquid discharge device 440 as a single unit.

In still another example, a cap that forms a part of the maintenance unit may be secured to the carriage mounting the head so that the head, the carriage, and the maintenance unit form a single unit to form the liquid discharge device.

Like the liquid discharge device 440 illustrated in FIG. 16, the tube 456 is connected to the head 404 mounting the head tank 441 or the channel part 444 so that the head 404 and the supply unit 494 (channel part 444, for example) form a single unit as the liquid discharge device 440.

The main scan moving unit may be a guide only. The supply unit may be a tube(s) only or a loading unit only.

The pressure generator used in the “head” is not limited to a particular type of pressure generator. The pressure generator is not limited to the piezoelectric actuator (or a laminated-type piezoelectric element) described in the above-described embodiments, and may be, for example, a thermal actuator that employs a thermoelectric transducer element, such as a thermal resistor, or an electrostatic actuator including a diaphragm and opposed electrodes.

The terms “image formation”, “recording”, “printing”, “image printing”, and “fabricating” used herein may be used synonymously with each other.

### EXAMPLES

Hereinafter, the present embodiment will be described more specifically with reference to examples, but the present embodiment is not limited to these examples.

### Examples 1 to 9, Comparative Examples 1 to 15

The liquid discharge head illustrated in FIG. 7 was manufactured by the method illustrated in FIGS. 11A to 11C and FIGS. 12A to 12C, and a liquid discharge apparatus including the obtained liquid discharge head was manufactured and evaluated. The results are illustrated in Tables 1 and 2.

As the piezoelectric layer, PZT formed by a sol-gel method was used. The formation temperature of the CMOS element was set to 850° C. and 900° C., and the evaluation was performed using the formation temperature of PZT as a parameter. The formation temperature of the CMOS element and the formation temperature of PZT are illustrated in Tables 1 and 2. Here, the formation temperature of the CMOS element is the temperature in the impurity diffusion heat treatment (FIG. 11G), and is the temperature of the final high-temperature heat treatment performed at the CMOS element forming step.

As illustrated in Tables 1 and 2, the liquid discharge heads of both the nozzle plate vibration system (FIG. 6A) and conventional discharge system (FIG. 6B) were manufactured and evaluated.

### [Evaluation]

The evaluation was made on the operation of the CMOS element, the piezoelectric characteristics (displacement amount) of the piezoelectric element, the droplet discharge operation, and the compatibility of the CMOS operation and the discharge operation.

### [Operation of CMOS Element]

The evaluation of the operation of the CMOS element was determined based on whether the CMOS circuit normally operates in a case where both the CMOS circuit and the piezoelectric element are formed as in the present embodiment, as in a case where only the CMOS circuit is formed. Specific evaluation criteria are as follows.
Good: A threshold voltage shift of each CMOS was within ±5% and a predetermined CMOS circuit operated normally.
Acceptable: Although the threshold voltage shift of each CMOS was ±5% or larger, the predetermined CMOS circuit operated.
Poor: The predetermined CMOS circuit did not operate normally.

### <Piezoelectric Characteristics (Displacement Amount) of Piezoelectric Element>

The piezoelectric characteristics of the piezoelectric element were evaluated based on whether or not a desired diaphragm displacement amount was obtained at a predetermined applied voltage. The evaluation criteria are as follows.

The evaluation criteria are as follows.
High: A displacement amount equal to or larger than the desired amount (significantly exceeding+20%) was obtained.
Medium: The desired displacement amount (±20%) was obtained.
Low: The displacement amount was equal to or smaller than a predetermined desired displacement amount (less than −20%).
   Low (Defective): The displacement amount was equal to or smaller than the desired displacement amount (significantly less than −20%).

### <Droplet Discharge Operation>

The evaluation of the droplet discharge operation was determined by whether or not a predetermined ink droplet (amount) can obtain a desired or higher ink discharge speed at a predetermined applied voltage. The evaluation criteria are as follows.
Good: A desired or higher ink discharge speed (significantly exceeding+20%) was obtained.
Acceptable: The desired ink discharge speed (±20%) was obtained.
Poor: The ink discharge speed was equal to or lower than the desired ink discharge speed (significantly lower than −20%). Alternatively, no discharge.

### <Compatibility of CMOS Operation and Discharge Operation>

The evaluation criteria are as follows.
Good: Both the CMOS element operation and droplet discharge operation are good.
Acceptable: The CMOS element operation and the droplet discharge operation are good and acceptable, respectively, or acceptable and good, respectively.
Poor: Other than the above (either of them is poor or both of them are poor).

TABLE 1

| | | | | Difference in | | | | |
|---|---|---|---|---|---|---|---|---|
| | | | | film | | Piezoelectric | | |
| | | | | formation | | characteristics | Nozzle plate vibration system | |
| | CMOS | Piezoelectric | | temperature | Operation of | of | | Compatibility |
| | element | element | Wiring | between | CMOS | piezoelectric | | between CMOS |
| | formation | formation | process | CMOS and | element | element | Droplet | operation and |
| | temperature | temperature | temperature | piezoelectric | (electronic | (displacement | discharge | discharge |
| | [° C.] | [° C.] | [° C.] | body [° C.] | component) | amount) | operation | operation |
| Comparative | 850 | 900 | 500 | −50 | Poor | High | Good | Poor |
| example 1 | | | | | | | | |
| Comparative | 850 | 800 | 500 | 50 | Poor | Middle | Good | Poor |
| example 2 | | | | | | | | |
| Example 1 | 850 | 750 | 500 | 100 | Acceptable | Middle | Good | Acceptable |
| Example 2 | 850 | 700 | 500 | 150 | Good | Middle | Good | Good |
| Example 3 | 850 | 600 | 500 | 250 | Good | Low | Good | Good |
| Example 4 | 850 | 500 | 500 | 350 | Good | Low | Acceptable | Acceptable |
| | | | | | | (defective) | | |
| Comparative | 900 | 900 | 500 | 0 | Poor | High | Good | Poor |
| example 3 | | | | | | | | |
| Example 5 | 900 | 800 | 500 | 100 | Acceptable | Middle | Good | Acceptable |
| Example 6 | 900 | 750 | 500 | 150 | Good | Middle | Good | Good |
| Example 7 | 900 | 700 | 500 | 200 | Good | Middle | Good | Good |
| Example 8 | 900 | 600 | 500 | 300 | Good | Low | Good | Good |
| Example 9 | 900 | 500 | 500 | 400 | Good | Low | Acceptable | Acceptable |
| | | | | | | (defective) | | |

TABLE 2

| | | | | Difference in | | | | |
|---|---|---|---|---|---|---|---|---|
| | | | | film | | Piezoelectric | Not nozzle plate vibration | |
| | | | | formation | | characteristics | system (conventional discharge | |
| | CMOS | Piezoelectric | | temperature | Operation of | of | system) | |
| | element | element | Wiring | between | CMOS | piezoelectric | | Compatibility |
| | formation | formation | process | CMOS and | element | element | Droplet | between CMOS |
| | temperature | temperature | temperature | piezoelectric | (electronic | (displacement | discharge | operation and |
| | [° C.] | [° C.] | [° C.] | body [° C.] | component) | amount) | operation | discharge operation |
| Comparative | 850 | 900 | 500 | −50 | Poor | High | Good | Poor |
| example 4 | | | | | | | | |
| Comparative | 850 | 800 | 500 | 50 | Poor | Middle | Acceptable | Poor |
| example 5 | | | | | | | | |
| Comparative | 850 | 750 | 500 | 100 | Acceptable | Middle | Acceptable | Poor |
| example 6 | | | | | | | | |
| Comparative | 850 | 700 | 500 | 150 | Good | Middle | Poor | Poor |
| example 7 | | | | | | | | |
| Comparative | 850 | 600 | 500 | 250 | Good | Low | Poor | Poor |
| example 8 | | | | | | | | |
| Comparative | 850 | 500 | 500 | 350 | Good | Low | Poor | Poor |
| example 9 | | | | | | (defective) | | |
| Comparative | 900 | 900 | 500 | 0 | Poor | High | Good | Poor |
| example 10 | | | | | | | | |
| Comparative | 900 | 800 | 500 | 100 | Acceptable | Middle | Acceptable | Poor |
| example 11 | | | | | | | | |
| Comparative | 900 | 750 | 500 | 150 | Good | Middle | Poor | Poor |
| example 12 | | | | | | | | |
| Comparative | 900 | 700 | 500 | 200 | Good | Middle | Poor | Poor |
| example 13 | | | | | | | | |
| Comparative | 900 | 600 | 500 | 300 | Good | Low | Poor | Poor |
| example 14 | | | | | | | | |
| Comparative | 900 | 500 | 500 | 400 | Good | Low | Poor | Poor |
| example 15 | | | | | | (defective) | | |

According to the above results, for example, the following can be said.

Comparing Examples 1 to 4 with Comparative Examples 1 and 2, in a case where the CMOS element formation temperature is 850° C., when the piezoelectric element formation temperature is in a range of 500° C. to 750° C., by combining with the nozzle diaphragm system, it is possible to achieve both the CMOS operation and the droplet discharge operation. As in Examples 2 and 3, when the piezoelectric element formation temperature is in the range of 600° C. to 700° C., the compatibility between the CMOS operation and the droplet discharge operation is further improved.

Comparing Examples 5 to 9 with Comparative Example 3, in a case where the CMOS element formation temperature is 900° C., when the piezoelectric element formation temperature is in the range of 500° C. to 800° C., both the CMOS operation and the droplet discharge operation can be achieved by combining with the nozzle diaphragm system. As in Examples 7 and 8, when the piezoelectric element formation temperature is in the range of 600° C. to 750° C., the compatibility between the CMOS operation and the droplet discharge operation is further improved.

In Examples 4 and 9, the droplet discharge operation was low, and an applied voltage higher than a predetermined voltage was required, but since a stable compatible operation was achieved, it was regarded as acceptable.

The above-described Examples and Comparative Examples are examples of results when verifying the liquid discharge head. As described in the above-described embodiment, in the liquid discharge head of the present embodiment, it is essential that the formation temperature of the piezoelectric element satisfies a predetermined requirement and that the piezoelectric element is of the nozzle plate vibration system. In the liquid discharge heads obtained in Comparative Examples 1 to 5 and 10, the formation temperature of the piezoelectric element did not satisfy the predetermined requirement, and in the liquid discharge heads obtained in other Comparative Examples, since the conventional discharge system was adopted instead of the nozzle plate vibration system, it was not possible to achieve both the CMOS operation and the discharge operation.

It is considered that the tendency similar to that of the above-described liquid discharge head can be obtained when the piezoelectric device is verified. When the piezoelectric device is manufactured under the temperature condition similar to that in Comparative Examples 1 to 5 and 10 described above, the example included in the present embodiment is obtained and it is considered that both the CMOS operation and the piezoelectric characteristics can be achieved. However, the CMOS operation is at a level of barely acceptable, and is inferior to that in other examples (for example, there is a site that does not operate).

Aspects of the present embodiment are, for example, as follows.

<1> A piezoelectric device including:
a CMOS element and a piezoelectric element formed on a same substrate,
the piezoelectric element including a lower electrode layer, a piezoelectric layer, and an upper electrode layer,
the substrate including a void on a side opposite to the piezoelectric layer across the lower electrode layer,
the piezoelectric device including a first insulating film on a lower side of the lower electrode layer and a second insulating film on an upper side of the upper electrode layer,
the first insulating film under the piezoelectric layer thinner than the second insulating film above the piezoelectric layer.
   <2> The piezoelectric device according to <1>, in which the piezoelectric element includes a piezoelectric layer containing one or more selected from lead zirconate titanate (PZT) and potassium sodium niobate (KNN).
   <3> The piezoelectric device according to <1> or <2> including: a through hole that penetrates the piezoelectric element and communicates with the void, in which the piezoelectric element is formed around the through hole.
   <4> A liquid discharge head including: the piezoelectric device according to <3>, in which the void is supplied with liquid, and the through hole is a nozzle hole that discharges the liquid.
   <5> The liquid discharge head according to <4>, in which the substrate includes a liquid contact film at a site in contact with the liquid, and includes a water-repellent film on a surface on a side on which the liquid is discharged.
   <6> A liquid discharge device including: the liquid discharge head according to <4> or <5>.
   <7> The liquid discharge device according to <6>, in which one of a head tank that stores liquid to be supplied to the liquid discharge head, a carriage that mounts the liquid discharge head, a supply unit that supplies the liquid to the liquid discharge head, a maintenance unit that maintains the liquid discharge head in good condition, and a main scan moving unit that moves the liquid discharge head in a main scanning direction, and the liquid discharge head are combined to form a single unit.
   <8> A liquid discharge apparatus, the apparatus including: the liquid discharge head according to any one of <1> to <5> or the liquid discharge device according to <6> or <7>.
   <9> A method of manufacturing a piezoelectric device, the method including:
a CMOS element forming step of forming a CMOS element on a substrate;
a piezoelectric element forming step of forming a piezoelectric element on the substrate;
a wiring layer forming step of forming a wiring layer of the CMOS element and a wiring layer of the piezoelectric element; and
a void forming step of forming a void in the substrate,
wherein the CMOS element and the piezoelectric element are formed on a same substrate,
at the CMOS element forming step or the piezoelectric element forming step, a first insulating film is formed in a region where the piezoelectric element is formed,
at the piezoelectric element forming step, a lower electrode layer, a piezoelectric layer, an
upper electrode layer, and a second insulating film are formed on the first insulating film,
at the void forming step, the void is formed on a side opposite to the piezoelectric layer across the lower electrode layer in the substrate, and
the CMOS element forming step, the piezoelectric element forming step, the wiring layer forming step, and the void forming step are performed in this order.
   <10> The method of manufacturing the piezoelectric device according to <9>, in which the first insulating film under the piezoelectric layer is made thinner than the second insulating film above the piezoelectric layer.
   <11> The method of manufacturing the piezoelectric device according to <9> or <10>, in which at the piezoelectric element forming step, the piezoelectric element is formed at temperature lower than temperature of heat treatment for impurity diffusion when NMOS or PMOS source electrode and drain electrode in the CMOS element are formed.
   <12> The method of manufacturing the piezoelectric device according to <11>, in which at the piezoelectric element forming step, the piezoelectric element is formed at temperature lower by 100° C. or more than the temperature of the heat treatment for impurity diffusion.
   <13> The method of manufacturing the piezoelectric device according to <12>, in which at the piezoelectric element forming step, the piezoelectric element is formed at temperature of 800° C. or lower.
   <14> The method of manufacturing the piezoelectric device according to <12>, in which at the piezoelectric element forming step, the piezoelectric element is formed at temperature of 500° C. or higher.
   <15> The method of manufacturing the piezoelectric device according to any one of <9> to <14>, in which at the piezoelectric element forming step, the piezoelectric layer is formed by a sol-gel method, a sputtering method, or a chemical vapor deposition (CVD) method.
   <16> The method of manufacturing the piezoelectric device according to any one of <9> to <15>, in which at the void forming step, a through hole that penetrates the piezoelectric element and communicates with the void is formed.
   <17> A method of manufacturing a liquid discharge head, the method including: the method of manufacturing the piezoelectric device according to <16>, in which the through hole is a nozzle hole that discharges liquid from the void.
   <18> The method of manufacturing the liquid discharge head according to <17>, further including, after the void forming step, a liquid contact film and water-repellent film forming step of forming a liquid contact film at a site in contact with the liquid in the substrate and forming a water-repellent film on a surface on a side on which the liquid is discharged.

### [Aspect 1]

A device manufacturing method for manufacturing a piezoelectric device, the device manufacturing method includes:
forming a CMOS element on a first surface of a substrate;
forming a piezoelectric element on the first surface of the substrate on which the CMOS element is formed;
forming a first insulating film in a region where the piezoelectric element is formed when forming the CMOS element or the piezoelectric element,
forming a lower electrode layer, a piezoelectric layer, an upper electrode layer, and a second insulating film on the first insulating film when forming the piezoelectric element;
forming a CMOS wiring layer of the CMOS element and a piezoelectric wiring layer of the piezoelectric element after forming the CMOS element and the piezoelectric element on the substrate; and
forming a void in the substrate from a second surface opposite to the first surface of the substrate after forming the CMOS wiring layer and the piezoelectric wiring layer on the substrate.

### [Aspect 2]

In the device manufacturing method according to aspect 1, the forming the first insulating film forms the first insulating film to be thinner than the second insulating film, and the first insulating film is closer to the first surface of the substrate than the second insulating film.

### [Aspect 3]

The device manufacturing method according to aspect 1, further includes: heat treatment for impurity diffusion for forming a NMOS source electrode and a drain electrode or a PMOS source electrode and a drain electrode in the CMOS element at a first temperature,
wherein the forming the piezoelectric element forms the piezoelectric element at a second temperature lower than the first temperature of the heat treatment for the impurity diffusion.

### [Aspect 4]

In the device manufacturing method according to aspect 3, the second temperature is lower by 100° C. or more than the first temperature.

### [Aspect 5]

In the device manufacturing method according to aspect 4, the forming the piezoelectric element forms the piezoelectric element at the second temperature of 800° C. or lower.

### [Aspect 6]

In the device manufacturing method according to aspect 5, the forming the piezoelectric element forms the piezoelectric element at the second temperature of 500° C. or higher and 800° C. or lower.

### [Aspect 7]

In the device manufacturing method according to aspect 1, the forming the piezoelectric element using a sol-gel method, a sputtering method, or a chemical vapor deposition (CVD) method to form the piezoelectric layer.

### [Aspect 8]

The device manufacturing method according to aspect 1, further includes: forming a through hole penetrating through the piezoelectric element and communicating with the void after forming the void.

### [Aspect 9]

A head manufacturing method for manufacturing a liquid discharge head, the head manufacturing method includes: the device manufacturing method according to aspect 8; and forming the void in the substrate as a liquid chamber; forming the through hole as a nozzle hole from which a liquid in the liquid chamber is discharged.

### [Aspect 10]

The head manufacturing method according to aspect 9, further includes: forming a liquid contact film on an inner surface of the liquid chamber; and forming a water-repellent film on a nozzle surface on which the nozzle hole is formed.

### [Aspect 11]

A piezoelectric device comprising:
a substrate having a void;
a CMOS element on a first surface of the substrate;
a first insulating film on the first surface of the lower electrode layer and
a piezoelectric element on the first insulating film, the piezoelectric element including:
a lower electrode layer having a first surface on the first insulating film;
a piezoelectric layer having a first surface on a second surface opposite to the first surface of the lower electrode layer;
an upper electrode layer having a first surface on a second surface opposite to the first surface of the piezoelectric layer; and
a second insulating film on the second surface of the upper electrode layer, the second insulating film having a thickness thicker than the first insulating film.

### [Aspect 12]

The piezoelectric device according to aspect 11 further includes: a through hole penetrating through the piezoelectric element and communicating with the void, wherein the piezoelectric element is around the through hole.

### [Aspect 13]

A liquid discharge head includes: the piezoelectric device according to aspect 12, wherein the void has a liquid chamber accommodating a liquid, and the through hole has a nozzle hole from which the liquid in the liquid chamber is discharged.

### [Aspect 14]

In the liquid discharge head according to aspect 13, wherein the substrate includes: a liquid contact film on an inner surface of the liquid chamber, and a water-repellent film on a nozzle surface on which the nozzle hole is formed.

### [Aspect 15]

A liquid discharge apparatus includes: the liquid discharge head according to aspect 13; and at least one of: a head tank storing a liquid to be supplied to the liquid discharge head; a carriage mounting the liquid discharge head; a supply unit configured to supply the liquid to the liquid discharge head; a maintenance unit configured to maintain the liquid discharge head; or a main scan moving unit configured to move the liquid discharge head in a main scanning direction, combined with the liquid discharge head to form a single unit.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

This patent application is based on and claims priority to Japanese Patent Application No. 2022-118758, filed on Jul. 26, 2022, in the Japan Patent Office, the entire disclosure of which is hereby incorporated by reference herein.

### REFERENCE SIGNS LIST

100 silicon substrate
104 gate electrode (without impurity diffusion)
104a impurity ion implantation region (gate electrode)
106 impurity ion implantation region (source electrode and drain electrode)
107 impurity ion implantation region (substrate electrode)
108 channel doped region (low-concentration impurity ion implantation region)
108b channel doped region (low-concentration impurity diffusion region)
108c channel doped region (low-concentration impurity diffusion region)
110 CMOS element substantial part
111 well
112 field oxide film
113 gate oxide film
114 gate electrode (impurity diffusion activated)
115 sidewall
116a source electrode
116b drain electrode
117 substrate electrode
118 channel region (threshold voltage matched)
120 CMOS element
132 through hole
135 metal wiring
140 CMOS element component
150 nozzle hole
160 piezoelectric element
161 lower electrode layer
162 piezoelectric layer
163 upper electrode layer
171 first insulating film
172 second insulating film
175 substantial displacement portion of diaphragm
176 ink liquid contact film
177 nozzle water-repellent film
181 vibration region
190 void
250 nozzle
251 nozzle plate
260 piezoelectric element (thin film piezoelectric element)
270 diaphragm base layer
280 diaphragm (diaphragm all layers)
290 individual chamber
291 ink channel (individual pressurized liquid chamber)
295 ink channel
296 ink channel (fluid resistance)
360 piezoelectric element layer (thin film piezoelectric element layer)
370 diaphragm base layer
380 diaphragm (diaphragm all layers)
385 substantial displacement portion of diaphragm

### CITATION LIST

### Patent Literature

[PTL 1]
Japanese Translation of PCT International Application Publication No. JP-T-2019-530601

The invention claimed is:

1. A device manufacturing method for manufacturing a piezoelectric device, the device manufacturing method comprising:
forming a CMOS element on a first surface of a substrate;
forming a piezoelectric element on the first surface of the substrate on which the CMOS element is formed;
forming a first insulating film in a region where the piezoelectric element is formed when forming the CMOS element or the piezoelectric element,
forming a lower electrode layer, a piezoelectric layer, an upper electrode layer, and a second insulating film on the first insulating film when forming the piezoelectric element;
forming a CMOS wiring layer of the CMOS element and a piezoelectric wiring layer of the piezoelectric element after forming the CMOS element and the piezoelectric element on the substrate; and
forming a void in the substrate from a second surface opposite to the first surface of the substrate after forming the CMOS wiring layer and the piezoelectric wiring layer on the substrate.

2. The device manufacturing method according to claim 1, wherein:
the forming the first insulating film forms the first insulating film to be thinner than the second insulating film, and
the first insulating film is closer to the first surface of the substrate than the second insulating film.

3. The device manufacturing method according to claim 1, further comprising:
performing heat treatment for impurity diffusion for forming a NMOS source electrode and a drain electrode or a PMOS source electrode and a drain electrode in the CMOS element at a first temperature,
wherein the forming the piezoelectric element forms the piezoelectric element at a second temperature lower than the first temperature of the heat treatment for the impurity diffusion.

4. The device manufacturing method according to claim 3, wherein:
the second temperature is lower by 100° C. or more than the first temperature.

5. The device manufacturing method according to claim 4, wherein:
the forming the piezoelectric element forms the piezoelectric element at the second temperature of 800° C. or lower.

6. The device manufacturing method according to claim 5, wherein:
the forming the piezoelectric element forms the piezoelectric element at the second temperature of 500° C. or higher and 800° C. or lower.

7. The device manufacturing method according to claim 1, wherein:
the forming the piezoelectric element uses a sol-gel method, a sputtering method, or a chemical vapor deposition (CVD) method to form the piezoelectric layer.

8. The device manufacturing method according to claim 1, further comprising:
forming a through hole penetrating through the piezoelectric element and communicating with the void after forming the void.

9. A head manufacturing method for manufacturing a liquid discharge head, the head manufacturing method comprising:
performing the device manufacturing method according to claim 8;
forming the void in the substrate as a liquid chamber; and
forming the through hole as a nozzle hole from which a liquid in the liquid chamber is discharged.

10. The head manufacturing method according to claim 9, further comprising:
forming a liquid contact film on an inner surface of the liquid chamber; and
forming a water-repellent film on a nozzle surface on which the nozzle hole is formed.

11. A piezoelectric device comprising:
a substrate having a void;
a CMOS element on a first surface of the substrate;
a first insulating film on the first surface of the substrate;
a piezoelectric element on the first insulating film, the piezoelectric element including:
a lower electrode layer having a first surface on the first insulating film;
a piezoelectric layer having a first surface on a second surface opposite to the first surface of the lower electrode layer; and
an upper electrode layer having a first surface on a second surface opposite to the first surface of the piezoelectric layer; and
a second insulating film on the second surface of the upper electrode layer, the second insulating film having a thickness thicker than the first insulating film.

12. The piezoelectric device according to claim 11 further comprising:
a through hole penetrating through the piezoelectric element and communicating with the void,
wherein the piezoelectric element is around the through hole.

13. A liquid discharge head comprising:
the piezoelectric device according to claim 12, wherein the void has a liquid chamber accommodating a liquid, and
the through hole has a nozzle hole from which the liquid in the liquid chamber is discharged.

14. The liquid discharge head according to claim 13, wherein the substrate includes:
a liquid contact film on an inner surface of the liquid chamber, and
a water-repellent film on a nozzle surface on which the nozzle hole is formed.

15. A liquid discharge apparatus comprising:
the liquid discharge head according to claim 13; and
at least one of:
a head tank storing a liquid to be supplied to the liquid discharge head;
a carriage mounting the liquid discharge head;
a supply unit configured to supply the liquid to the liquid discharge head;
a maintenance unit configured to maintain the liquid discharge head; or
a main scan moving unit configured to move the liquid discharge head in a main scanning direction,
combined with the liquid discharge head to form a single unit.
